(19) United States
(12) Patent Application Publication
(10) Pub. No.: US 2008/0122007 A1
(43) Pub. Date: May 29, 2008

(54) Semiconductor device and fabrication process thereof

(75) Inventors: Shinichi Kawai, Kawasaki (JP); Takashi Saiki, Kawasaki (JP); Naoyoshi Tamura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/812,516

(22) Filed: Jun. 19, 2007

Related U.S. Application Data
(63) Continuation of application No. PCT/JP05/23055, filed on Dec. 15, 2005.

(30) Foreign Application Priority Data
Dec. 20, 2004 (JP) 2004-367691

(51) Int. Cl. H01L 27/092

(52) U.S. Cl. 257/374; 257/E27.063

(57) ABSTRACT

A semiconductor device includes a first polycrystalline semiconductor gate electrode structure formed in a first device region of a substrate via a gate insulation film and having a stacked structure in which a lower polycrystalline semiconductor layer and an upper polycrystalline semiconductor layer are stacked consecutively, the first polycrystalline gate electrode structure being doped to the second conductivity type, a second polycrystalline semiconductor gate electrode structure formed in a second device region of the substrate via a gate insulation film and having a stacked structure in which a lower polycrystalline semiconductor layer and an upper polycrystalline semiconductor layer are stacked consecutively, the second polycrystalline gate electrode structure being doped to the first conductivity type, a pair of diffusion regions of the second conductivity type formed in the first device region at respective lateral sides of the first polycrystalline semiconductor gate electrode structure, and a pair of diffusion regions of the first conductivity type formed in the second device region at respective lateral sides of the second polycrystalline semiconductor gate electrode structure, wherein, in each of the first and second polycrystalline semiconductor gate electrode structures, the lower polycrystalline semiconductor layer comprises semiconductor crystal grains of a grain diameter smaller than semiconductor crystal grains constituting the upper polycrystalline semiconductor layer, in each of the first and second polycrystalline semiconductor gate electrode structures, the lower polycrystalline semiconductor layer has a dopant concentration level equal to or higher than a dopant concentration level of the upper polycrystalline semiconductor layer.

### CROSS-REFERENCE TO RELATED APPLICATION

The present invention is a continuation application filed under 35 U.S.C. 111(a) claiming benefit under 35 U.S.C. 120 and 365(c) of Japanese patent application 2004-367691 filed on Dec. 20, 2004 and PCT application JP2005/23055 filed on Dec. 15, 2005, the entire contents of each are incorporated herein as reference.

### BACKGROUND OF THE INVENTION

The present invention generally relates to semiconductor devices and more particularly to a semiconductor device having a polysilicon gate electrode and fabrication process thereof.

MOS transistors are used extensively in semiconductor integrated circuit devices.

For improvement of operational speed of MOS transistors, decrease of gate length is effective, and thus, efforts are being made for miniaturization of MOS transistors. As a result, ultrafine MOS transistors having a gate length of less than 60 nm are realized these days.

In order to attain the desired high speed operation, in other words, large current drivability and suppress short channel effect at the same time with such ultrafine MOS transistors, it is important to reduce the film thickness of gate insulation film in accordance with so-called scaling law.

More specifically, the density of carriers induced in the channel region of a MOS transistor is proportional to a gate capacitance, while the gate capacitance is in inverse proportion to the film thickness of the gate insulation film. Thus, it is possible to increase the current drivability of the MOS transistor by reducing the film thickness of the gate insulation film.

Further, it should be noted that the electric field induced by the gate electrode right underneath thereof is distributed between the gate insulation film and the depletion layer formed in the channel region right underneath the gate insulation film. Thus, by reducing the film thickness of the gate insulation film, the electric field applied to the depletion layer is increased and it becomes possible to suppress the short channel effect effectively.

On the other hand, when the film thickness of the gate insulation film is reduced as such, there arise new problems such as deterioration of reliability of the gate insulation film.

More specifically, in the case such thin gate insulation film is used, there tends to occur the problem that impurity element introduced into the gate electrode as dopant penetrates through the gate insulation film and invades into the channel. When invasion of impurity element into to such a channel region is caused, there occurs the problem of deterioration of TDDB (time-dependent dielectric breakdown) characteristics.

Further, in the case the film thickness of the gate insulation film is reduced to 10 nm or less, the effect of depletion layer extending upward with minute distance in the gate electrode from the interface to the gate insulation film becomes no longer ignorable, and there occurs increase of effective film thickness of the gate insulation film. As a result, there occurs decrease of density of carriers induced in the channel region, resulting in decrease of current drivability of the MOS transistor.

### Patent Reference 1

Japanese Laid-Open Patent Application 2001-068662 official gazette

### Patent Reference 2

Japanese Laid-Open Patent Application 06-244136 official gazette

### SUMMARY OF THE INVENTION

Here, the construction of the MOS transistor of a related art of the present invention and the fabrication process thereof will be explained for the case of n-channel MOS transistor with reference to FIGS. 1 and 2.

Referring to FIG. 1, a device isolation region 42 is formed on a p-type silicon substrate 41 so as to define a device region, and a p-type well 43 is formed in the device region. Further, by conducting a thermal oxidation process and a thermal annealing process in a nitrogen gas ambient, an insulation film 44 is formed on the surface of the silicon substrate 41 as the gate insulation with the film thickness of 2 nm, for example.

Further, a polysilicon film is deposited on the entire surface of the silicon substrate 41 by a CVD process so as to cover the insulation film 44 with a thickness of 100 nm, and P (phosphor) is introduced as the dopant impurity element by an ion implantation process under an acceleration energy of 10 keV with a dose of 6×10¹⁵ cm⁻². Further, by patterning the polysilicon film thus obtained, there is formed a polysilicon gate electrode pattern 45 with a gate length of 60 nm.

Furthermore, P or As (arsenic) is introduced into the silicon substrate 41 by an ion implantation process while using the polysilicon gate electrode pattern 45 as a mask. With this, a pair of n-type extension diffusion regions 46 are formed in the p-type well 43 at respective sides of the gate electrode 45.

Further, a pair of sidewall insulation films 47 are formed at respective sides of the gate electrode pattern 45, and P or As ions are introduced by an ion implantation process while using the gate electrode pattern 45 and the sidewall insulation films as a mask. With this, there are formed n⁺-type diffusion regions 48 in the device region 43 at respective outer sides of the sidewall insulation films as the source and drain regions of the p-channel MOS transistor.

Furthermore, a rapid thermal annealing process (RTA) is applied to the structure thus introduced with the impurities element by the ion implantation process at the temperature of 1000° C. for activation of the injected impurity element.

Finally, a silicide layer 49 is formed on the polysilicon gate electrode pattern 45 and on the surface of the n⁺-type diffusion region 48 by a salicide process.

FIG. 2 shows a cross-sectional diagram of the gate electrode pattern 45 taken along a line A-A′, in other words, taken along the gate width direction of FIG. 1.

Referring to FIG. 2, the gate electrode pattern 45 is formed of a polysilicon film of a monolayer construction, wherein it can be seen that the polysilicon film is formed of columnar Si crystal grains extending from a top surface of the polysilicon film to a bottom surface of the polysilicon film. With the polysilicon film having such a microstructure, the crystal grain boundary 51 of the Si crystals extend also continuously from the top surface to the bottom surface of the polysilicon film.

It should be noted that the grain diameter of such columnar Si crystal grains changes depending on the film thickness of the polysilicon film thus formed as shown in FIGS. 3A and 3B, such that the grain diameter of the Si crystal grains increases as shown in FIG. 3A in the case the film thickness of the polysilicon film is large. In the case the film thickness of the polysilicon film is small, on the other hand, the grain diameter of the Si crystal grains in the polysilicon film decreases as shown in FIG. 3B. Such dependence of grain diameter of the Si crystal grains upon the film thickness appears particularly conspicuously in the case the film thickness of the polysilicon film is 100 nm or less.

Meanwhile, it has been discovered, in the investigation made on the TDDB characteristics for the MOS transistors having the polysilicon gate electrode 45 on the gate insulation film 44, that there occurs improvement of TDDB characteristics in the case the grain diameter of the Si crystal grains is suppressed in the polysilicon gate electrode pattern 45. This effect appears particularly conspicuously in the case of an n-channel MOS transistor in which the polysilicon gate electrode pattern 45 is doped with P.

Thus, it can be seen that, in order to improve the TDDB characteristics of MOS transistors, it is effective to decrease the film thickness of the polysilicon gate electrode pattern 45.

However, with the polysilicon gate electrode pattern 45 of reduced film thickness, there arises a problem that the gate insulation film vital to operation of MOS transistor is affected at the time of formation of the silicide layer 49. Further, taking into consideration the fact that the silicide layer 49 on the gate electrode pattern 45 is formed at the same time to the silicide layer 49 on the source/drain region 48, it is difficult to simply reduce the film thickness of the polysilicon gate electrode pattern 45. More specifically, it should be noted that the distance between the silicide layer 49 on the source/drain region 48 and the silicide layer 49 on the gate electrode pattern 45 separated with each other by the sidewall insulation film 47 is reduced when the thickness of the gate electrode pattern 45 is reduced, while this tends to lead to the risk of causing short circuit therebetween.

Contrary to this, there is a technology in a related art of the present invention shown in FIG. 4 of conducting the formation of the polysilicon film in two steps, first forming a lower polysilicon film 52 with small thickness, followed by formation of an upper polysilicon film 53 with large thickness, and form a microstructure in which the grain diameter of the Si crystal grains 50 is suppressed in the lower polysilicon film 52 and the grain diameter of the Si crystal grains in the upper polysilicon film 53 is increased.

With the structure of FIG. 4, for example, it can be seen that a crystal grain boundary extends in the upper polysilicon film 53 from the top part to the bottom part of the film 53 continuously. Further, in the lower polysilicon film 52, to, it can be seen that the crystal grain boundary 51 extends continuously from the top part to the bottom part of the film 52.

Thus, the technology of FIG. 4 achieves the control of grain diameter of the Si crystal grains in the film by controlling the film thickness of the polysilicon film. Thus, there is a proposal of improving the TDDB characteristics of the MOS transistor by using a polysilicon film of such a structure for the gate electrode.

Meanwhile, Patent Reference 1 describes a technology of forming a thin amorphous silicon film on a gate insulation film, crystallizing the same to form a polysilicon film of Si crystal grains of small grain diameter, forming a thick polysilicon film further thereon with a larger crystal grain diameter, and conduct ion implantation process of an impurity element into the polysilicon film of the dual layer structure thus obtained.

Further, Patent Reference 2 describes a technology of obtaining a polysilicon electrode film of relaxed stress in the form of a polysilicon film of small grain diameter, by repeating the process of depositing a thin doped amorphous silicon film and causing crystallization therein.

In the technology of Patent Reference 1, however, there arises a problem noted below in relation to the selection of ion implantation energy.

FIGS. 5A-5C show the case of conducting ion implantation process of an impurity element at relatively low energy after formation of the polysilicon film of dual layer structure similar to the one shown in FIG. 4.

Referring to FIG. 5A, there is caused a deposition of thin undoped polysilicon film 52 of Si crystal grains of small grain diameter on the gate insulation film 44 at first, followed by deposition of a thick undoped polysilicon film 53 of larger grain diameter thereon. Further, in the step of FIG. 5B, P is introduced into the polysilicon film of the dual layer structure thus formed by an ion implantation process with low acceleration energy.

In this case, the atoms of P thus introduced do not reach the lower part of the upper polysilicon film 53 as shown in FIG. 53B but remain in the upper part of the film 53, only the upper part of the polysilicon film 53 thus introduced with P undergoes transition to an amorphous state 54 as a result of the ion implantation process.

Thus, as a result of the thermal annealing process applied to such a structure, the amorphous state part 54 undergoes crystallization as shown in FIG. 5C, and the initial polysilicon film 53 changes to a polysilicon layer 55 in the amorphous state part 54 thereof, wherein the polysilicon layer 55 is characterized by Si crystal grains of larger grain diameter as compared with the polysilicon film 53. At the same time to this, there occurs diffusion of P from the amorphous state part 54, and the entirety of the initial polysilicon film 53 is doped to n⁺-type down to the bottom part of the polysilicon layer 55.

On the other hand, the impurity element caused diffusion from the impurity injection region 54 does not reach the lower polysilicon film 52 or only very small amount of the impurity element reaches the lower polysilicon film 52, and thus, it is not possible to introduce the n-type impurity element into the lower polysilicon film 52 with satisfactory concentration.

In the case the polysilicon film of the multilayer structure such as the one shown in FIG. 5C is used for the gate electrode of a MOS transistor, therefore, the diffusion of the dopant element from the polysilicon gate electrode into the channel region (so-called channeling) is thus suppressed effectively by the lowermost polysilicon film 52 of the Si crystal grains of small grain diameter.

However, with such a construction, there is a tendency that depletion takes place in the polysilicon gate electrode when a gate voltage is applied thereto in view of the low impurity concentration level of the polysilicon gate electrode particularly at the lower part thereof. Thereby, there is caused increase of the effective film thickness in the gate electrode, and this results in decrease of the current drivability of the transistor.

On the other hand, in the case the ion implantation process is conducted to a deep level with large energy in the structure of FIG. 6A corresponding to FIG. 5A, the entirety of the upper polysilicon film 53 undergoes change into amorphous state 57 as shown in FIG. 6B, and the whole amorphous layer 57 causes transition to the crystalline state as shown in FIG. 6C when a crystallization process is applied to the amorphous film 57 thereafter. With this, there is formed a polysilicon film 58 of monolayer structure of large grain diameter.

With such a polysilicon film 58, it is not possible to suppress the diffusion of the impurity element into the channel region.

On the other hand, with the method of Patent Reference 2, it is certainly possible to avoid the problem of gate depletion and the problem of deterioration of the TDDB characteristics caused by coarse grain texture of the polysilicon gate electrode, while there is imposed a constraint on the elements usable for the impurity element in view of the fact that the gate electrode is formed in the state in which the impurity element is doped. Thereby, there arises a problem that it is difficult to fabricate a semiconductor integrated circuit device having both a p-type gate electrode and an n-type gate electrode such as a CMOS device, or the like. When to form a p-type gate electrode and an n-type gate electrode by using such so-called in-situ doped gate electrode, it is necessary to form these by separate film-forming processes. However, formation of the gate electrodes with different film-forming processes is not realistic in dual-gate devices such as a CMOS device.

It is an object of the present invention to provide a semiconductor device and fabrication process thereof in which it is possible to improve the TDDB characteristics while suppressing depletion of the polysilicon gate electrode at the same time.

Another object of the present invention is to provide a semiconductor device and fabrication process thereof wherein it is possible to suppress short channel effect without complicating the fabrication process thereof.

In a first aspect, the present invention provides a semiconductor device, comprising:

a substrate;

a device isolation structure formed on said substrate, said device isolation structure defining a first device region of a first conductivity type and a second device region of a second conductivity type on said substrate;

a first polycrystalline semiconductor gate electrode structure formed in said first device region via a gate insulation film, said first polycrystalline semiconductor gate electrode structure having a stacked structure in which a lower polycrystalline semiconductor layer and an upper polycrystalline semiconductor layer are stacked consecutively, said first polycrystalline gate electrode structure being doped to said second conductivity type;

a second polycrystalline semiconductor gate electrode structure formed in said second device region via a gate insulation film, said second polycrystalline semiconductor gate electrode structure having a stacked structure in which a lower polycrystalline semiconductor layer and an upper polycrystalline semiconductor layer are stacked consecutively, said second polycrystalline gate electrode structure being doped to said first conductivity type;

a pair of diffusion regions of said second conductivity type formed in said first device region at respective lateral sides of said first gate electrode structure; and

a pair of diffusion regions of said first conductivity type formed in said second device region at respective lateral sides of said second gate electrode structure,

wherein, in each of said first and second polycrystalline semiconductor gate electrode structures, said lower polycrystalline semiconductor layer includes semiconductor crystal grains of a grain diameter smaller than semiconductor crystal grains forming said upper polycrystalline semiconductor layer,

in each of said first and second polycrystalline semiconductor gate electrode structures, said lower polycrystalline semiconductor layer has a dopant concentration level equal to or higher than a dopant concentration level of said upper polycrystalline semiconductor layer.

In another aspect, the present invention provides a semiconductor device, comprising:

a substrate;

a device isolation structure formed on said substrate, said device isolation structure defining a first device region of a first conductivity type and a second device region of a second conductivity type on said substrate;

a first polycrystalline semiconductor gate electrode structure formed in said first device region via a gate insulation film, said first polycrystalline semiconductor gate electrode structure having a stacked structure in which a lower polycrystalline semiconductor layer and an upper polycrystalline semiconductor layer are stacked consecutively, said first polycrystalline semiconductor gate electrode structure being doped to said second conductivity type;

a second polycrystalline semiconductor gate electrode structure formed in said second device region via a gate insulation film, said second polycrystalline semiconductor gate electrode structure having a stacked structure in which a lower polycrystalline semiconductor layer and an upper polycrystalline semiconductor layer are stacked consecutively, said second polycrystalline semiconductor gate electrode structure being doped to said first conductivity type;

a pair of diffusion regions of said second conductivity type formed in said first device region at respective lateral sides of said first polycrystalline semiconductor gate electrode structure;

a pair of diffusion regions of said first conductivity type formed in said second device region at respective lateral sides of said second polycrystalline semiconductor gate electrode structure;

wherein, in each of said first and second polycrystalline semiconductor gate electrode structures, said lower polycrystalline semiconductor layer comprises semiconductor crystal grains of a grain size smaller than semiconductor crystal grains constituting said upper polycrystalline semiconductor layer,

in each of said first and second polycrystalline semiconductor gate electrode structures, said lower polycrystalline semiconductor layer has a dopant concentration of 1×10²⁰ cm⁻³ or more.

Further, in another aspect, the present invention provides a semiconductor device, comprising:

a substrate;

a device isolation structure formed on said substrate, said device isolation structure defining a first device region of a first conductivity type and a second device region of a second conductivity type on said substrate;

a first polycrystalline semiconductor gate electrode structure formed in said first device region via a gate insulation film, said first polycrystalline semiconductor gate electrode structure having a stacked structure in which a lower polycrystalline semiconductor layer and an upper polycrystalline semiconductor layer are stacked consecutively, said first polycrystalline gate electrode structure being doped to said second conductivity type;

a second polycrystalline semiconductor gate electrode structure formed in said second device region via a gate insulation film, said second polycrystalline semiconductor gate electrode structure having a stacked structure in which a lower polycrystalline semiconductor layer and an upper polycrystalline semiconductor layer are stacked consecutively, said second polycrystalline gate electrode structure being doped to said first conductivity type;

a pair of diffusion regions of said second conductivity type formed in said first device region at respective lateral sides of said first polycrystalline semiconductor gate electrode structure; and

a pair of diffusion regions of said first conductivity type formed in said second device region at respective lateral sides of said second polycrystalline semiconductor gate electrode structure,

wherein, in each of said first and second polycrystalline semiconductor gate electrode structures, said lower polycrystalline semiconductor layer comprises semiconductor crystal grains of a grain diameter smaller than semiconductor crystal grains constituting said upper polycrystalline semiconductor layer,

wherein, in each of said first and second polycrystalline semiconductor gate electrode structures, said lower polycrystalline semiconductor layer has a smaller film thickness as compared with said upper polycrystalline semiconductor layer.

In another aspect, the present invention provides a method for fabricating a semiconductor device, comprising the steps of:

forming a first polycrystalline semiconductor film on a substrate via a gate insulation film;

doping said first polycrystalline semiconductor film with an impurity element of a first conductivity type by an ion implantation process;

forming a second polycrystalline semiconductor film over said first polycrystalline semiconductor film;

patterning said first and second polycrystalline semiconductor films to form a gate electrode structure in which said first and second polycrystalline semiconductor films are stacked; and

forming source and drain diffusion regions doped to said first conductivity type at respective lateral sides of said gate electrode structure and simultaneously doping said second polycrystalline semiconductor film in said gate electrode structure to said first conductivity type, by introducing an impurity element of a conductivity type identical to said first impurity element while using said gate electrode structure as a mask.

In another aspect, the present invention provides a method for fabricating a semiconductor device, comprising the steps of:

forming a first polycrystalline semiconductor film over a semiconductor substrate via a gate insulation film;

doping said first polycrystalline semiconductor film by an ion implantation process with an impurity element of a first conductivity type;

depositing a dummy gate pattern over said first polycrystalline semiconductor film;

forming a dummy gate pattern by patterning said first polycrystalline semiconductor film and a dummy insulation film thereon;

forming dummy sidewall insulation films on respective sidewall surfaces of said dummy gate pattern;

exposing said first polycrystalline semiconductor film by removing said dummy insulation film selectively with regard to said dummy sidewall insulation films;

forming source and drain regions over said semiconductor substrate by growing a semiconductor layer selectively at respective outer sides of said dummy sidewall insulation films and simultaneously forming a stacked gate electrode structure by selectively growing a second polycrystalline semiconductor layer over said first polycrystalline semiconductor layer; and

forming source and drain diffusion regions respectively in said source and drain regions by introducing an impurity element into said source by an ion implantation process and drain regions and simultaneously introducing said impurity element into said second polycrystalline semiconductor layer by an ion implantation process.

According to the present invention, it becomes possible to realize a semiconductor device suppressing depletion of polysilicon gate electrode and simultaneously suppressing deterioration of TDDB characteristics without complicating the fabrication process. According to such a semiconductor device, doping of the polysilicon gate electrode is achieved by ion implantation process, and thus, it is possible with the present invention to form a CMOS device, or the like, having polysilicon gates of different conductivity type, with simple process.

Further, according to the semiconductor device of the present invention, it is possible to form the source/drain regions on the semiconductor substrate such that the bottom edge of the source/drain regions is located near the surface of the silicon substrate by a regrowth process concurrently to the formation of the upper polysilicon layer of the polysilicon gate structure of multilayer construction and by doping the re-grown source/drain regions thus formed to the desired conductivity type by an ion implantation process. Thereby, it becomes possible to suppress the short channel effect effectively.

Other objects and further features of the present invention will become apparent from the following detailed description when read in conjunction with the attached drawings.

### BRIEF DESCRIPTION OF THE DRAWINGS

FIG. 1 is a schematic diagram showing the constitution of a MOS transistor according to a related art of the present invention;

FIG. 2 is a diagram showing an A-A cross-section of FIG. 1 with enlarged scale;

FIGS. 3A and 3B are diagrams explaining dependence of crystal grain diameter on film thickness;

FIG. 4 is a diagram showing the structure of a polysilicon film of multilayer structure obtained by a two-step growth process according to a related art of the present invention;

FIGS. 5A-5C are diagrams explaining the problem of the related art of the present invention;

FIGS. 6A-6C are further diagrams explaining the problem of the related art of the present invention;

FIG. 7 is a diagram explaining the principle of the present invention;

FIG. 8 is another diagram explaining the principle of the present invention;

FIGS. 9A-9R are diagrams showing the fabrication process of a CMOS device according to a first embodiment of the present invention;

FIGS. 10A-10G are diagrams showing the fabrication process of an n-channel MOS transistor according to a second embodiment of the present invention; and

FIGS. 11A-11K are diagrams showing the fabrication process of an n-channel MOS transistor according to a third embodiment of the present invention.

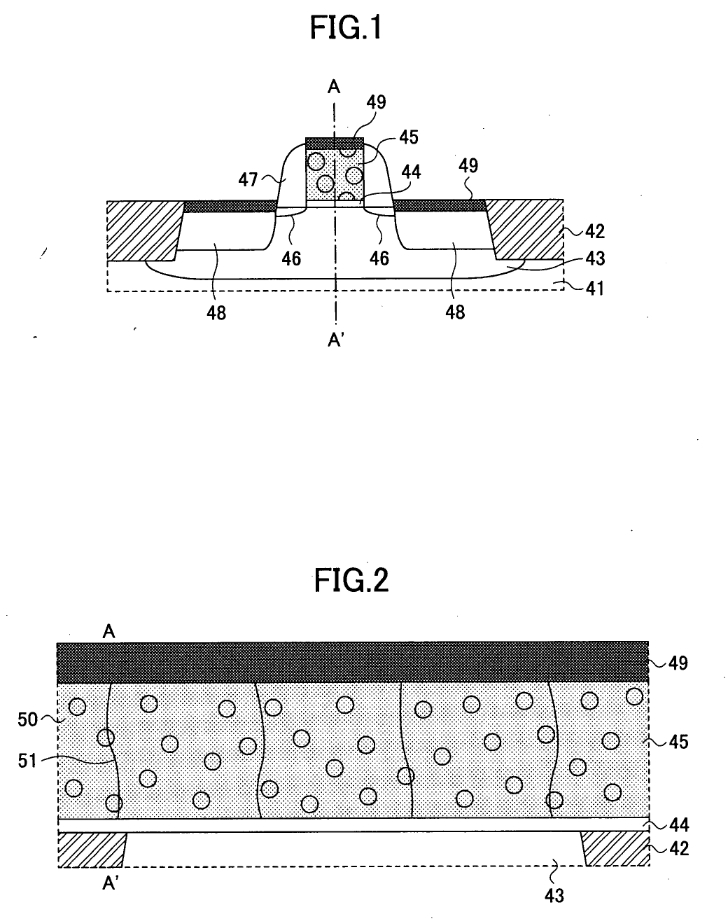

### DETAILED DESCRIPTION OF THE INVENTION

### Principle

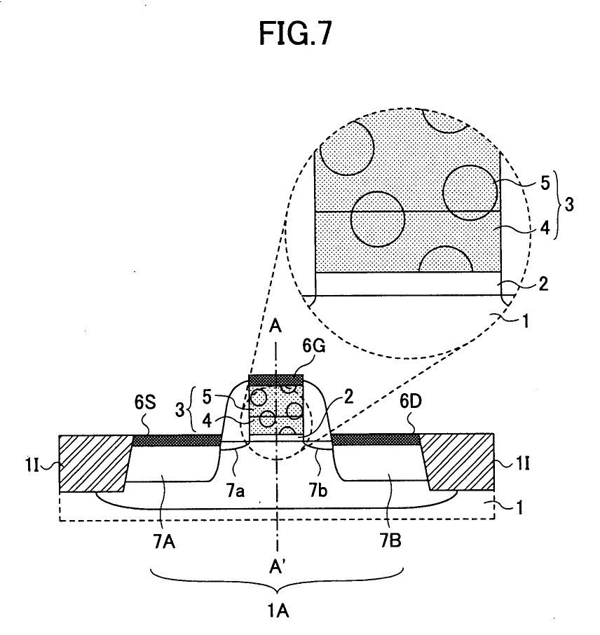

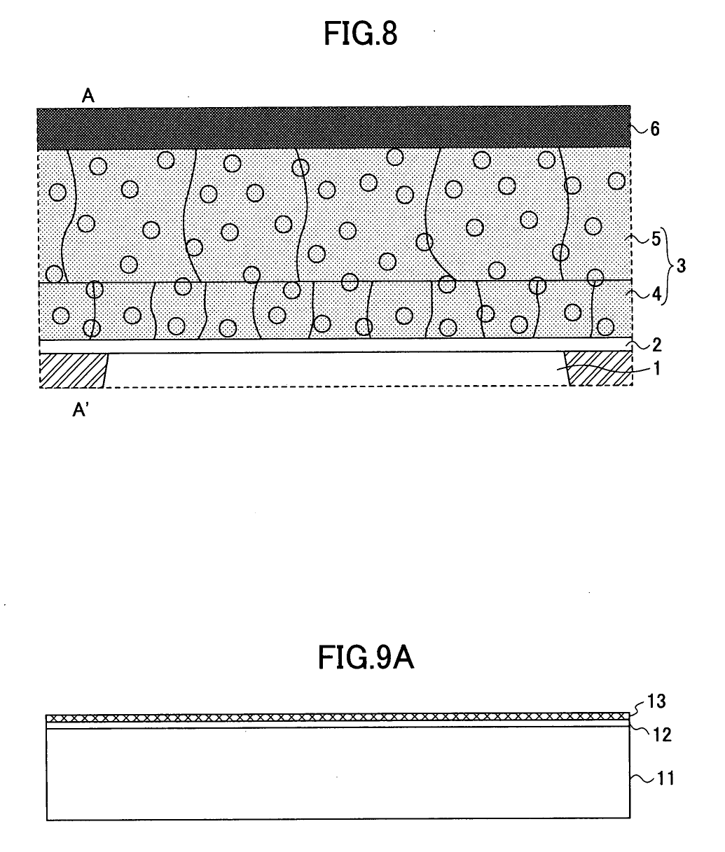

FIGS. 7 and 8 are diagrams showing the principle of the present invention.

Referring to FIG. 7, there is defined a device region 1A on a semiconductor substrate 1 by a device isolation structure 1I, and a polycrystalline semiconductor gate electrode 3 is formed on the silicon substrate 1 in the device region 1A via a gate insulation film 2.

Further, in the semiconductor substrate 1, there are formed source and drain extension regions 7a and 7b respectively in correspondence to a pair of mutually opposing sidewall surfaces of the polycrystalline semiconductor gate electrode 3, and there are formed source and drain regions 7A and 7B in continuation respectively to the source and drain extension regions 7a and 7b at the respective outer sides of the sidewall insulation films formed on the corresponding sidewall surfaces of the polycrystalline semiconductor gate electrode 3.

Further, on the surface of the source region 7A, there is formed a silicide layer 6S, while a silicide layer 6D is formed on the drain region 7B, and a silicide layer 6G is formed on the surface of the polysilicon gate electrode 3.

As shown in FIGS. 7 and 8, the polycrystalline semiconductor gate electrode 3 is formed of a lower polycrystalline semiconductor layer 4 of smaller film thickness and smaller crystal grain diameter and an upper polycrystalline semiconductor layer 5 formed over the lower polycrystalline semiconductor layer 4 with larger film thickness and larger crystal grain diameter. Thereby, the lower part polycrystalline semiconductor layer 4 is doped with higher impurity concentration than the upper side polycrystalline semiconductor layer 5.

With the semiconductor device of FIGS. 7 and 8, deterioration of TDDB characteristic is suppressed and the problem of the impurity element in gate electrode 3 invading into the channel region through the gate insulation film 2 is suppressed successfully, by forming the lower polycrystalline semiconductor layer 4 of the polycrystalline semiconductor gate electrode 3 such that the crystal grain diameter in the semiconductor layer 4 becomes smaller than the crystal grain diameter of the upper polycrystalline semiconductor layer 5, preferably such that 90% of the crystal grains in the semiconductor layer 4 have a grain diameter of 10-50 nm. Thereby, the problem that the impurity element in the gate electrode 3 cause invasion into the channel region through the gate insulation film 2 is successfully suppressed. To realize the crystal grain diameter of 10-50 nm for the polycrystalline semiconductor layer 4, it is sufficient to form the polycrystalline semiconductor layer 4 with the film thickness of 10-50 nm.

Further, with the semiconductor device of FIGS. 7 and 8, it becomes possible to avoid the problem of depletion of the gate electrode by setting the dopant concentration of the lower polycrystalline semiconductor layer 4 adjacent to the gate insulation film 2 to be higher than the dopant concentration level of the upper polycrystalline semiconductor layer 5, typically to the concentration of 1×10²⁰ cm⁻³ or more.

While such problem of gate depletion or deterioration of TDDB characteristics appears conspicuously in n-type semiconductor devices that use P for the dopant impurity element, the present invention is effective also in the case of p-type semiconductor devices that use B for the dopant element. Further, by doping such lower polycrystalline semiconductor layer 4 and the upper polycrystalline semiconductor layer 5 to p-type or n-type by an ion implantation process after formation thereof, it becomes possible to form dual gate semiconductor devices such as a CMOS device easily on a single semiconductor substrate.

### FIRST EMBODIMENT

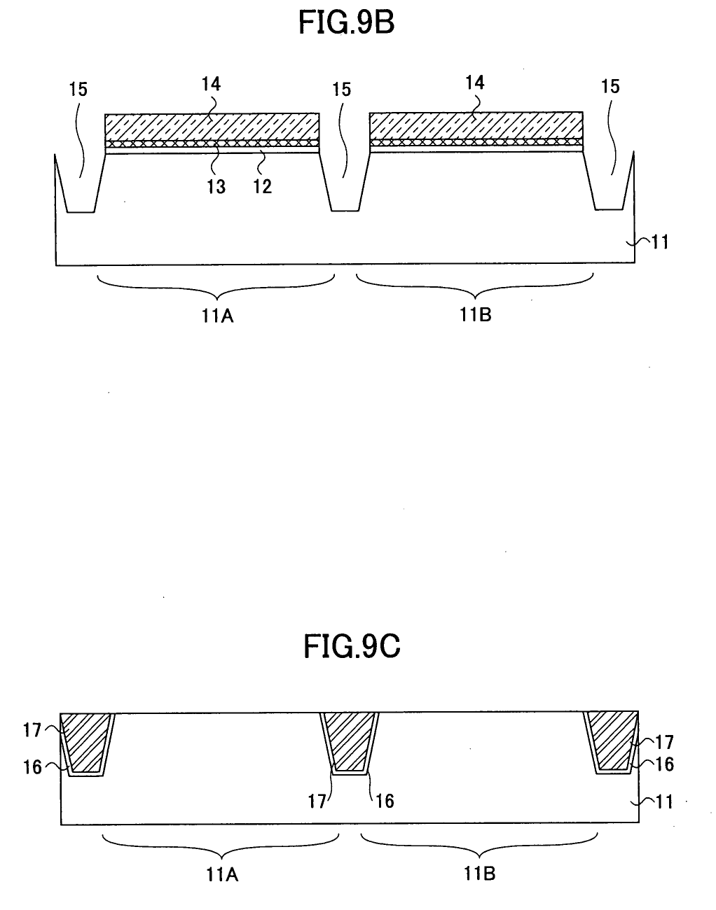

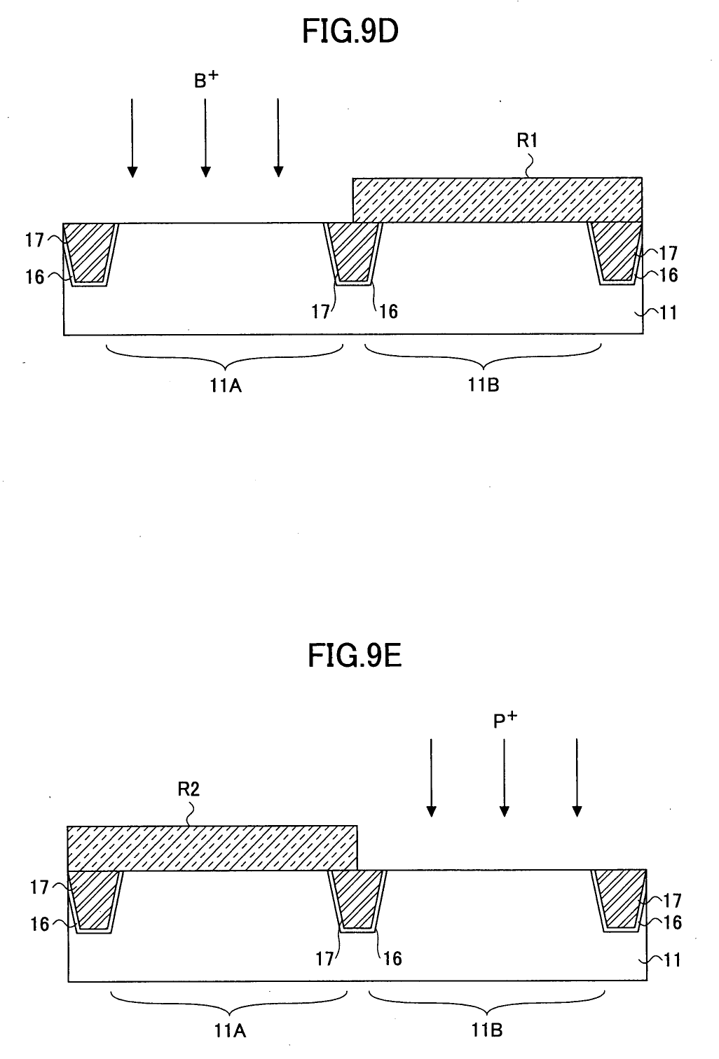

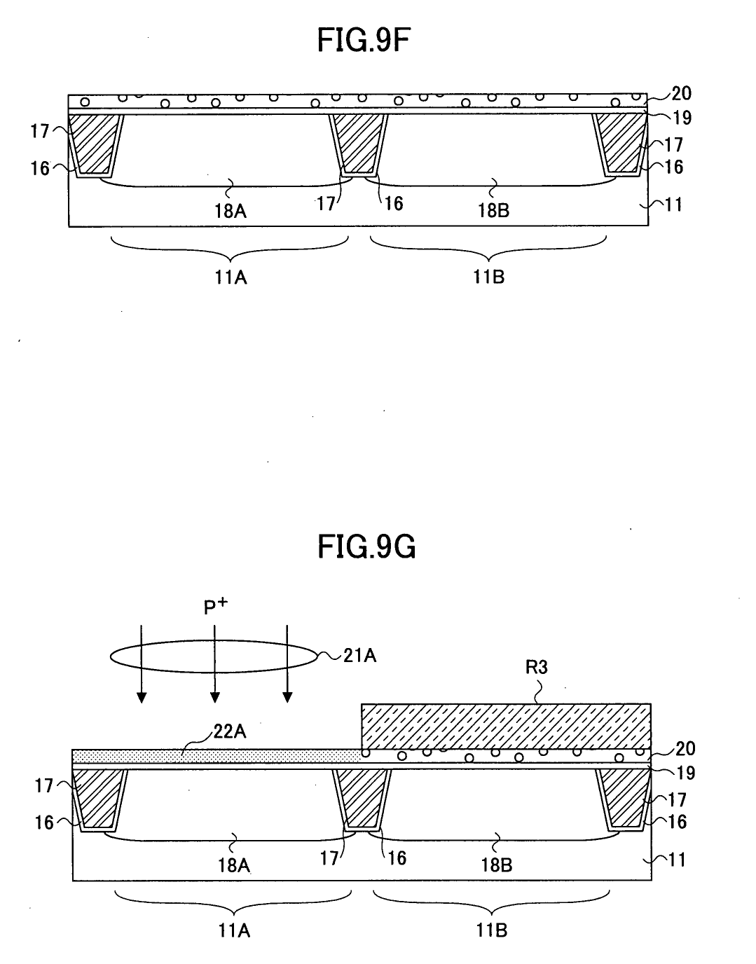

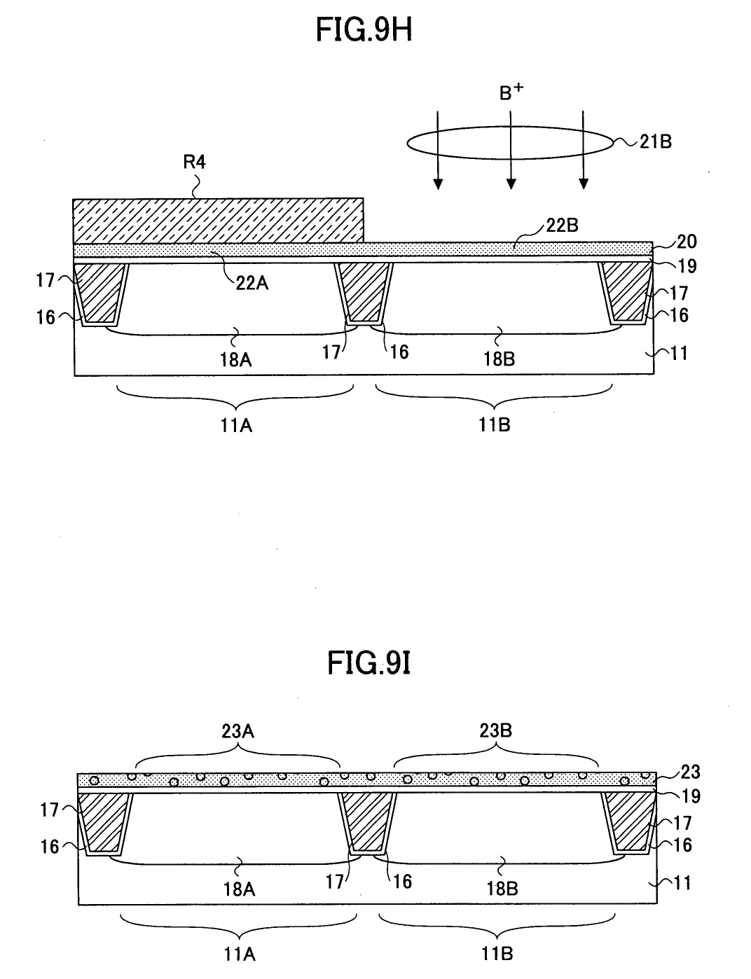

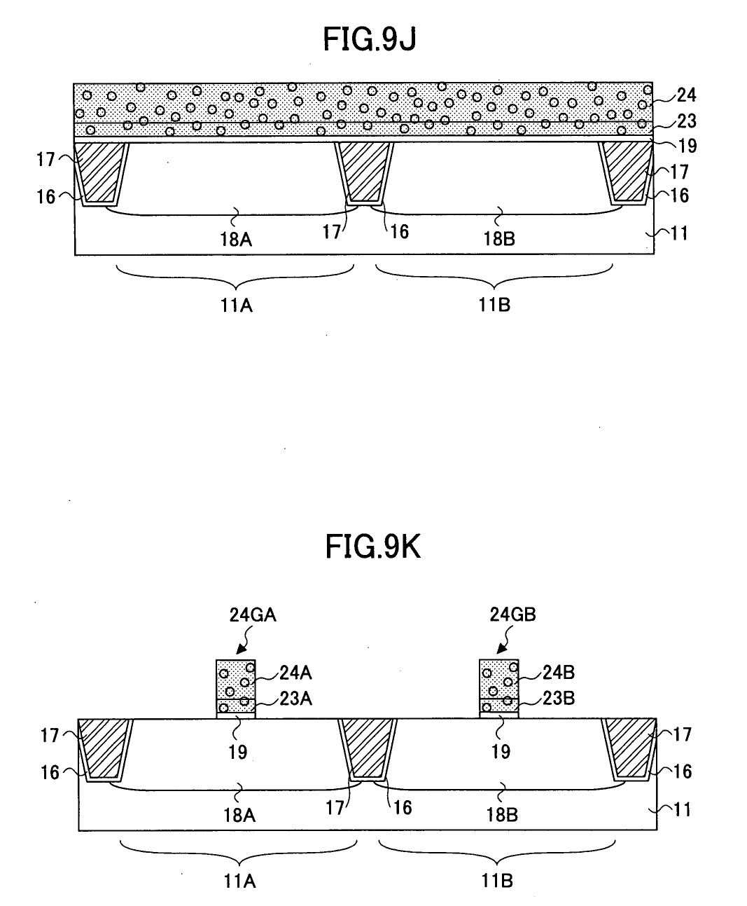

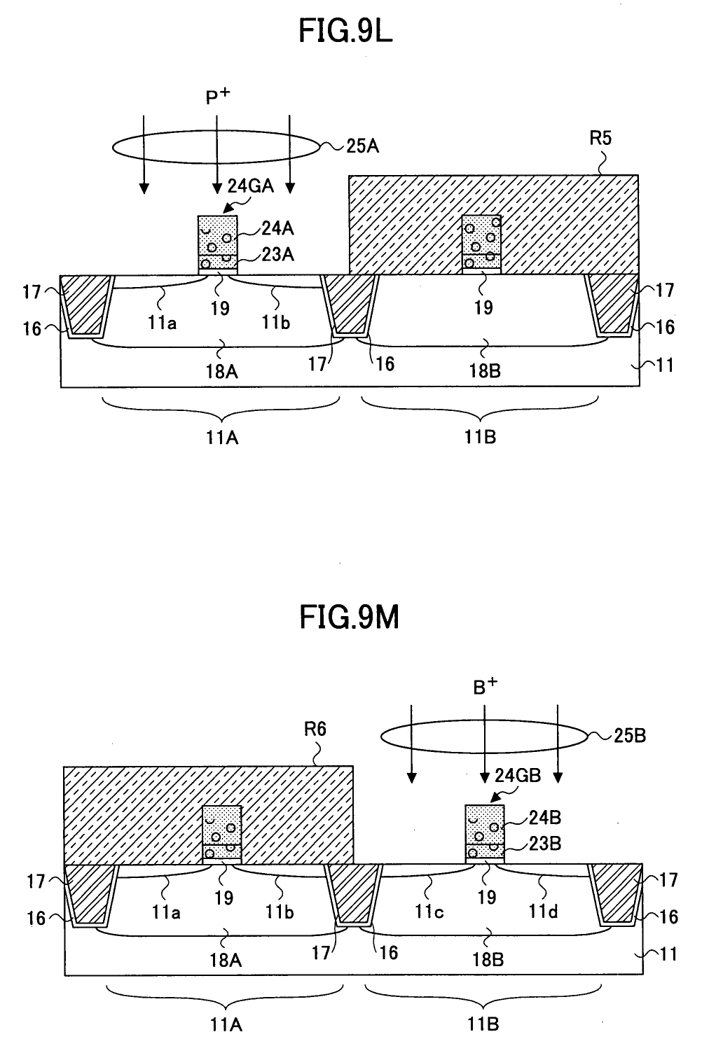

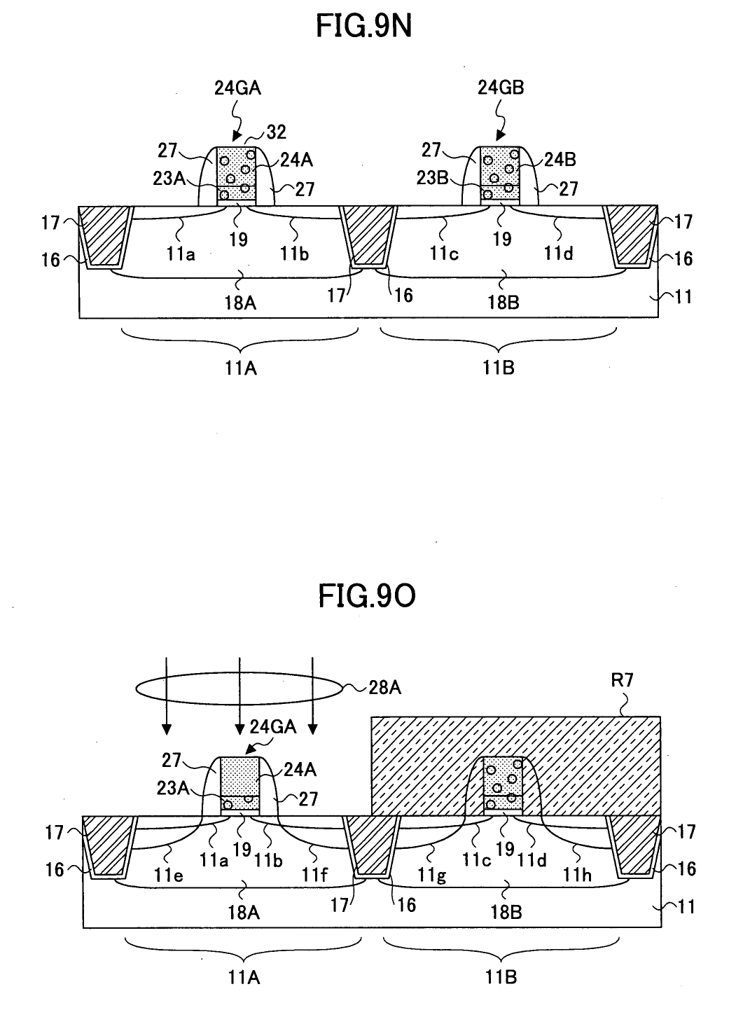

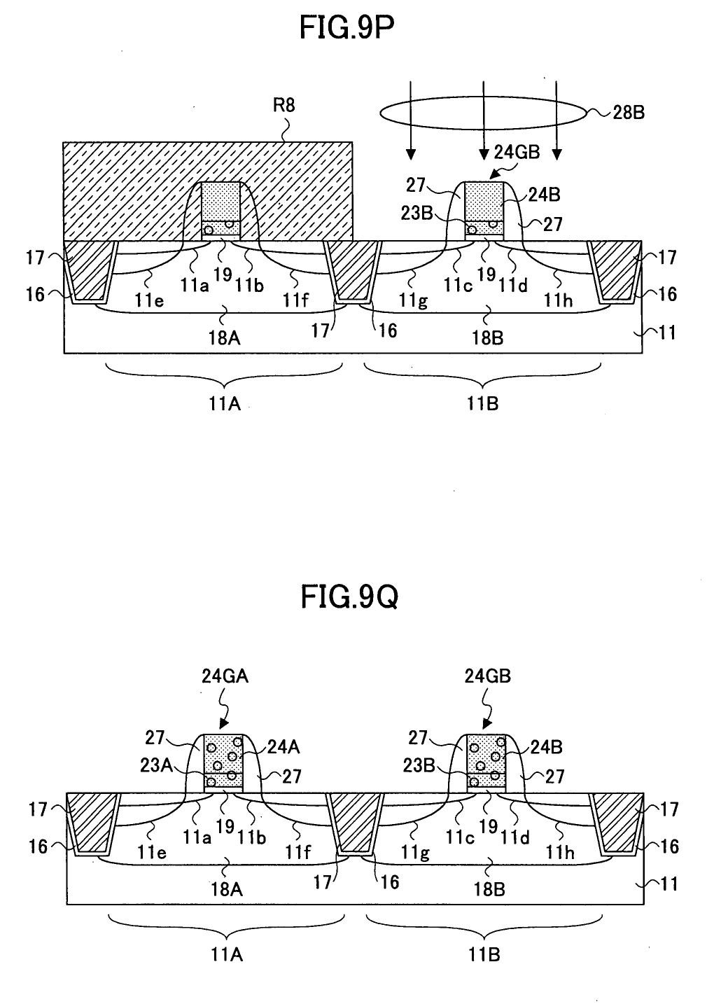

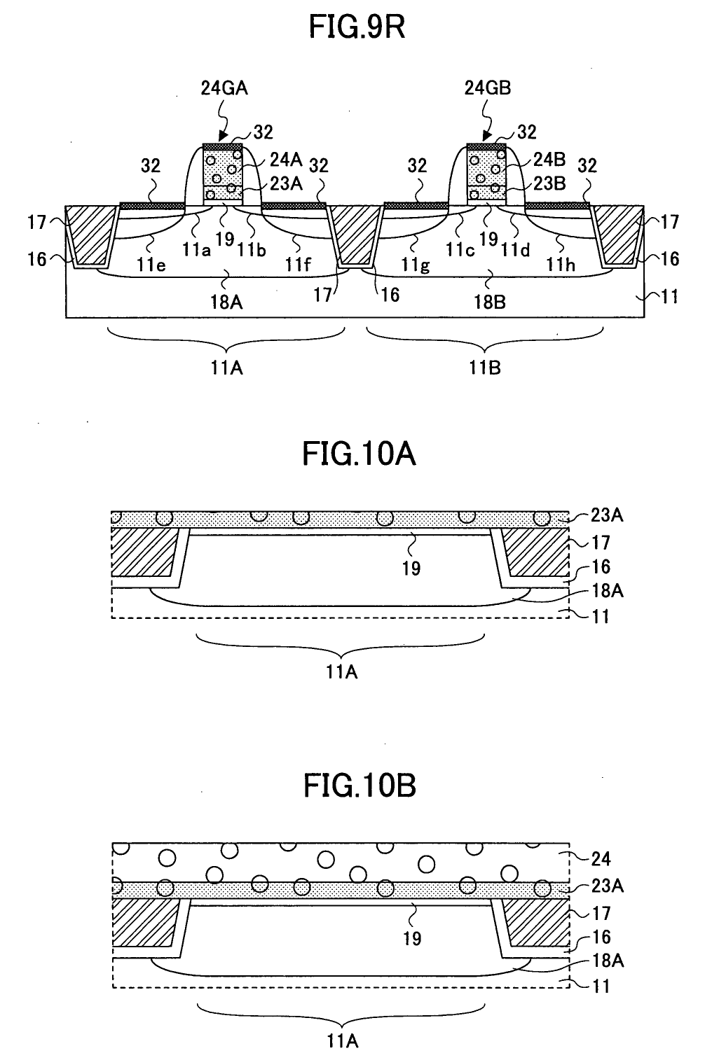

Next, fabrication process of a CMOS device according to a first embodiment of the present invention will be explained with reference to FIGS. 9A-9R.

Referring to FIG. 9A, there are formed a thermal oxide film 12 of the thickness of 10 nm and a silicon nitride film 13 of the thickness of 100 nm consecutively on a p-type silicon substrate 11 having a (100) surface orientation and a specific resistance of 10 Ωcm, wherein the silicon nitride film 13 and the thermal oxide film 12 are patterned in the step of FIG. 9B while using a resist pattern 14 as mask. Further, by etching the silicon substrate 11 by a dry etching process while using the SiN film 13 as a mask, there is formed a device isolation trench 15 on the silicon substrate 11 so as to define device regions 11A and 11B with a depth of 250 nm, for example. As will be explained later, the device regions 11A and 11B are formed respectively with an n-channel MOS transistor and a p-channel MOS transistor.

Further, the resist pattern 14 is removed in the step of FIG. 9C, and the entire substrate 11 in subjected to a thermal annealing process in an oxidizing ambient to form a thermal oxide film 16 on the surface of the device isolation trench 15 with a thickness of typically 5 nm. Thereafter, an SiO₂ film is deposited on the silicon substrate 11 by a high density plasma CVD process with a thickness of 500 nm, for example, so as to fill the device isolation trench 15.

Further, while using the silicon nitride film 13 and the thermal oxide film 12 as a stopper, the SiO₂ film 12 on the silicon substrate 11 is removed by a CMP (chemical mechanical polishing) process, followed by removal of the silicon nitride film 13 and the SiO₂ film 12 by etching. With this, a device isolation region 17 is formed.

Next, in the step of FIG. 9D, there is formed a resist pattern R1 on the structure of FIG. 9C so as to expose the device region 11A, and B⁺ is introduced under the acceleration energy of 120 kev with a dose of 2-3×10¹³ cm⁻² while using the resist pattern R1 as a mask.

Further, in the step of FIG. 9E, a resist pattern R2 exposing the device region 11B is formed, and P is introduced while using the resist pattern R2 as a mask by an ion implantation process conducted under an acceleration energy of 300 keV with a dose of 2-3×10¹³ cm⁻².

Further, in the step of FIG. 9F, the resist pattern R2 is removed, and thermal annealing process is conducted at the temperature of 950-1000° C. for 10-30 seconds, and with this, the respective impurity elements introduced into the wells 18A and 18B are activated. Thereby, the well 18A forms a p-type well 18A in the device region 11A while the well 18B forms an n-type well 18B in the device region 11B.

Further, in the step of FIG. 9F, B⁺ and P⁺ are introduced respectively into the device regions 11A and 11B by an ion implantation process with appropriate amount for the purpose of threshold adjustment, and a thermal oxide film is formed with a thickness of 2 nm by a thermal oxidation processing conducted at the temperature of 800-900° C. Furthermore, by conducting an annealing process in a nitrogen gas ambient, the thermal oxide film is nitrided and an SiON gate insulation film 19 is formed.

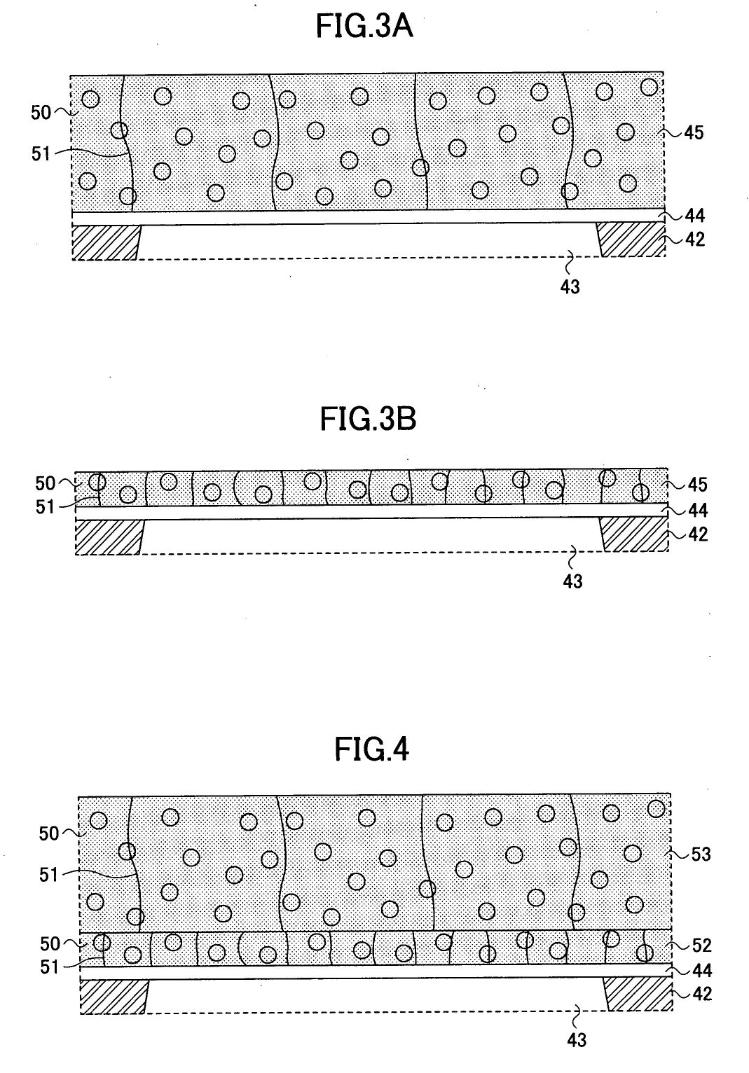

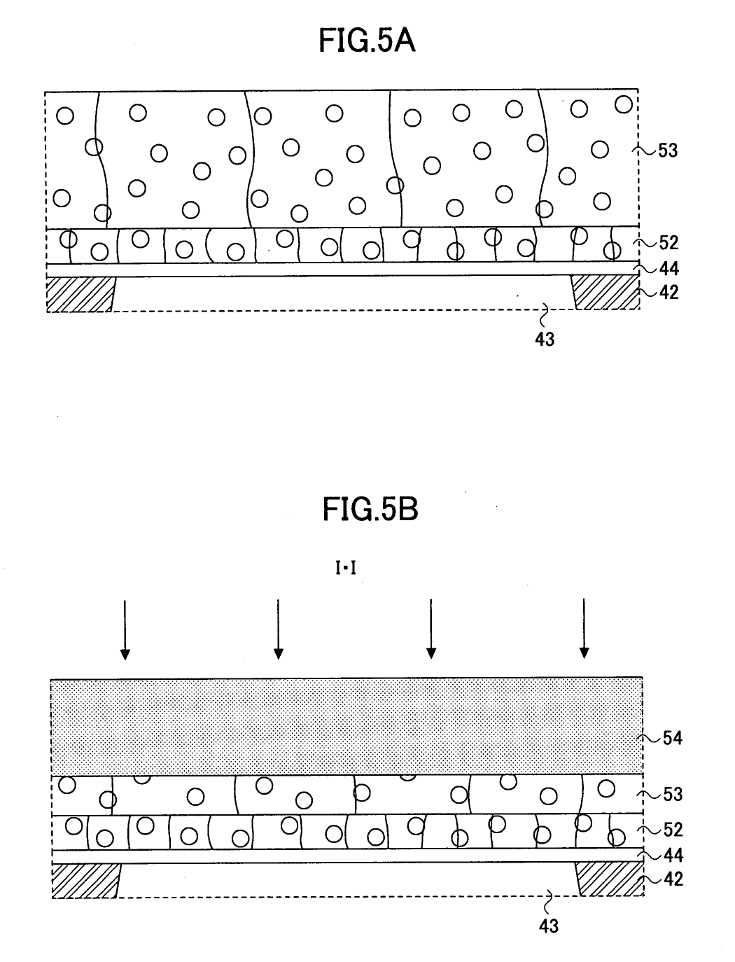

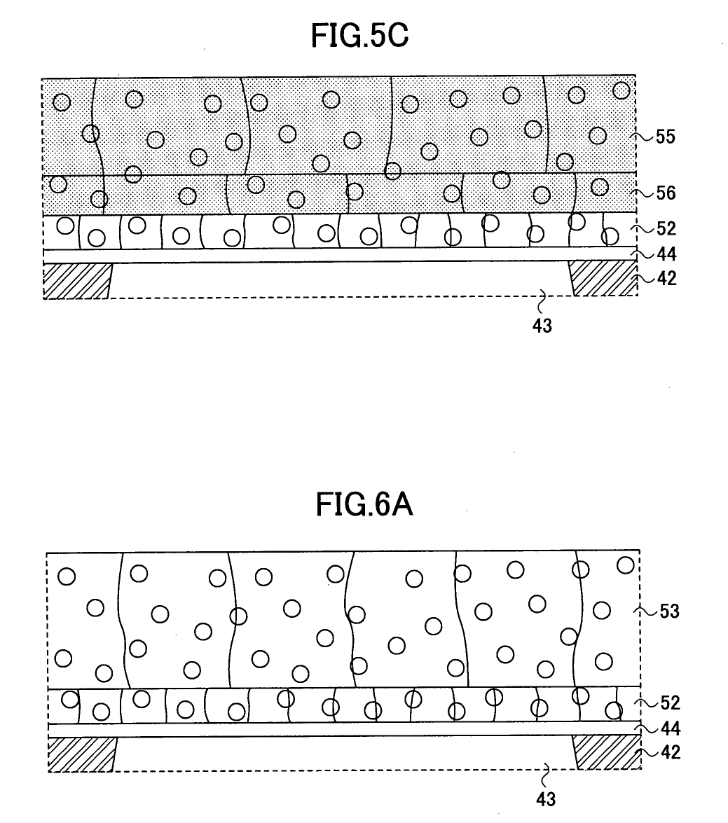

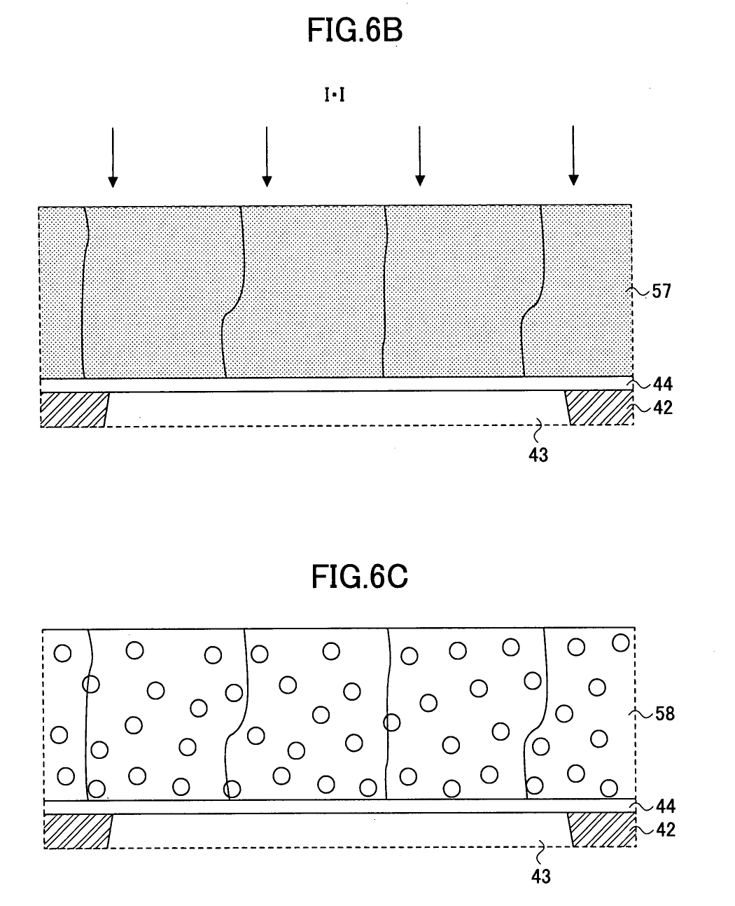

Further, in the step of FIG. 9F, a polysilicon film 20 is deposited subsequent to the formation of the SiON gate insulation film 19 by a low-pressure CVD process at a substrate temperature of 580-620° C., such as 600° C. for example, with a thickness of 10-50 nm, such as 30 nm for example. With the polysilicon film 20 thus formed, there are formed Si crystal grains of 10-50 nm generally equal to the film thickness therein, similarly to the case of FIG. 3B explained before.

Next, in the step of FIG. 9G, a resist pattern R3 exposing the device region 11A is formed on the polysilicon film 20 and P ions 21A are introduced thereto under the acceleration voltage of 3-30 keV, such as 10 keV for example, with a dose of 1-3×10¹⁵ cm⁻², such as 2×10¹⁵ cm⁻², while using the resist pattern R3 as a mask. As a result of such ion implantation process, a part 22A of the polysilicon film 20, to which the P ions were introduced, cause transition to an amorphous state.

Further, in the step of FIG. 9H, a resist pattern R4 exposing the device region 11B is formed on the polysilicon film 20, and B ions 21B are introduced thereto under the acceleration voltage of 1-10 keV, such as 5 keV for example, with a dose of 1-3×10¹⁵ cm⁻², such as 2×10¹⁵ cm⁻², while using the resist pattern R4 as a mask. As a result of such ion implantation process, a part 22B of the polysilicon film 20, to which the B ions were introduced, cause transition to an amorphous state.

Further, in the step of FIG. 9I, the structure of the FIG. 9H is subjected, after removing the resist pattern R4, to a thermal annealing process at the temperature of 500° C. or higher, such as 1000° C., for activation of the P ion and B ion thus introduced. With this thermal annealing process, the silicon film 20 including the amorphous regions 22A and 22B cause crystallization, and the silicon film 20 is transformed to a polysilicon film 23 including therein an n-type region 23A and a p-type region 23B as shown in FIG. 9I.

In the polysilicon film 23, while there is caused slight increase of grain diameter in the Si crystal grains constituting the film 23 as compared with the Si crystal grains in the polysilicon film 20, 90% or more, substantially 100% of the Si crystal grains have the grain diameter of 10-50 nm, which is generally equal to the film thickness of the polysilicon film 23, similarly to the case of the polysilicon film 20. It should be noted that such grain diameter distribution is confirmed by observing the vertical cross-section of the polysilicon film 23.

Further, in the step of FIG. 9J, there is formed a polysilicon film 24 on the structure of FIG. 9I with a low-pressure CVD process at the substrate temperature of 580-620° C., such as 600° C. for example, with a thickness of 50-100 nm, such as 70 nm for example. Here, it should be noted that the film thickness of the polysilicon film 24 is set such that the total film thickness of the polysilicon film 23 and the polysilicon film 24 becomes 100 nm. Because the polysilicon film 24 has a film thickness larger than that of the polysilicon film 23 underneath, the Si crystal grains in the film 24 are characterized by a larger grain diameter as compared with the Si crystal grains in the polysilicon film 23. In the present embodiment, it should be noted that the polysilicon film 24 is not doped.

Next, in the step of FIG. 9K, the polysilicon films 23 and 24 are subjected to a patterning process while using a resist pattern (not shown) of a width of 60 nm for example as a mask, and a polysilicon gate electrode structure 24GA of the n-channel MOS transistor is formed on the device region 11A in the form of the stack of the polysilicon films 23A and 24A formed on the gate insulation film 19 and doped to the n-type.

Further, in the device region 11B, a polysilicon gate electrode structure 24GB of the p-channel MOS transistor is formed on the device region 11B in the form of the stack of the polysilicon films 23B and 24B formed on the gate insulation film 19 and doped to the p-type. In the step of FIG. 9K, it should be noted that the thin SiON gate insulation film 19 is patterned also at the time of the patterning step of the polysilicon pattern.

Next, in the step of FIG. 9L, a resist pattern R5 is formed so as to expose the device region 11A, and P ions 25A are introduced into the device region 11A by an ion implantation process conducted under the acceleration energy of 5-15 keV with the dose of 5-10×10¹⁴ cm⁻² while using the resist pattern R5 and the stacked polysilicon gate structure 24GA as a mask. With this, there are formed n-type diffusion regions 11a and 11b on the surface of the silicon substrate 11 in correspondence to the respective sidewall surfaces of the stacked polysilicon gate structure 24GA respectively as the source and drain extension regions of the n-channel MOS transistor. As a result of this ion implantation process, it will be note that the top part of the polysilicon film 24A has been changed to an amorphous state.

Next, in the step of FIG. 9M, a resist pattern R6 is formed so as to expose the device region 11B, and B ions 25B are introduced into the device region 11B by an ion implantation process conducted under the acceleration energy of 1-5 keV with the dose of 5-10×10¹⁴ cm⁻² while using the resist pattern R6 and the stacked polysilicon gate structure 24GB as a mask. With this, there are formed p-type diffusion regions 11c and 11d on the surface of the silicon substrate 11 in correspondence to the respective sidewall surfaces of the stacked polysilicon gate structure 24GB respectively as the source and drain extension regions of the p-channel MOS transistor. As a result of this ion implantation process, it will be note that the top part of the polysilicon film 24B has been changed to an amorphous state.

Further, in the step of FIG. 9N, an SiO₂ film is deposited by a high-density plasma CVD process with the thickness of 40-80 nm on the structure of FIG. 9M after removing the resist pattern R6, and sidewall insulation films 27 are formed on the respective sidewall surfaces of the stacked gate electrode structures 24GA and 24GB by removing the SiO₂ film by a dry etching process acting perpendicularly to the substrate surface. With this deposition process, the entirety of the polysilicon films 24A and 24B undergoes crystallization again.

Next, in the step of FIG. 9O, a resist pattern R7 is formed on the silicon substrate 11 so as to expose the device region 11A, and P ions 28A are introduced into the device region 11A by an ion implantation process conducted under the acceleration energy of 10-20 keV with the dose of 5-10×10¹⁵ cm⁻² while using the resist pattern R7, the stacked polysilicon gate structure 24GA and the sidewall insulation films 27 as a mask. With this, there are formed source and drain regions 11e and 11f of n⁺-type in the device region 11A at respective outer sides of the sidewall insulation films. As a result of this ion implantation process, the top part of the polysilicon film 24A in the stacked gate electrode structure 24GA is changed again to an amorphous state.

Next, in the step of FIG. 9P, a resist pattern R8 is formed on the silicon substrate 11 so as to expose the device region 11B, and B ions 28B are introduced into the device region 11B by an ion implantation process conducted under the acceleration energy of 5-10 keV with the dose of 4-8×10¹⁵ cm⁻² while using the resist pattern R8, the stacked polysilicon gate structure 24GB and the sidewall insulation films 27 as a mask. With this, there are formed source and drain regions 11g and 11h of p⁺-type in the device region 11B at respective outer sides of the sidewall insulation films. As a result of this ion implantation process, the top part of the polysilicon film 24B in the stacked gate electrode structure 24GB is changed again to an amorphous state.

Next, in the step of FIG. 9Q, the structure of FIG. 9P is subjected, after removal of the resist pattern R8, to a thermal annealing process in a nitrogen gas ambient at the temperature of 1000-1050° C. for 0-10 seconds for activation of the impurity elements thus introduced into the substrate 11. Actually, the foregoing source and drain extension regions 11a-11d and the foregoing source and drain regions 11e-11h are formed as a result of this thermal annealing process. Further, associated with this thermal annealing process, the polysilicon film 24A of the stacked gate electrode structure 24GA and the polysilicon film 24B of the stacked gate electrode structure 24GB, changed to the amorphous state, undergo crystallization again.

Further, in the step of FIG. 9R, a Co film (not shown) is formed uniformly on the structure of FIG. 9Q by a sputtering process with a thickness of 10 nm, for example, followed by a thermal annealing process. Further, excessive Co film is removed by etching and thermal annealing process is applied again. With this, there are formed low-resistance CoSi₂ films 32 on the surfaces of the source and drain regions 11e and 11f and on the surface of the polysilicon film 24A of the stacked gate electrode structure 24GA of the n-channel MOS transistor. At the same time, the CoSi₂ films 32 are formed also on the surfaces of the source and drain regions 11g and 11h and on the surface of the polysilicon film 24B of the stacked gate electrode structure 24GB of the p-channel MOS transistor.

Further, by forming an interlayer insulation film not illustrated and forming via contact structure and interconnection structure according to the needs, there is completed a CMOS device in which the n-channel MOS transistor and the p-channel MOS transistor are connected in series. Further, in the case of forming an upper level interconnection structure on the interlayer insulation film in the form of a multilayer interconnection structure by using a damascene process, there are conducted formation of interconnection trenches and via-holes after formation of the interlayer insulation film, and a Cu interconnection layer is formed so as to fill such interconnection trenches and the via-holes. Further, excessive Cu layer on the interlayer insulation film is removed by a CMP process. If more complex interconnection structure is desired, such a process may be repeated as necessary.

According to the semiconductor device of the present embodiment thus formed, it should be noted that the lower polysilicon film is introduced with the impurity element of the corresponding conductivity type in each of the stacked gate electrode structures 24GA and 24GB before the upper polysilicon film is formed with low acceleration energy and high impurity concentration level, and it becomes possible to effectively resolve the problem of depletion caused in the polysilicon gate. Further, in view of small film thickness of the lower polysilicon film, the present invention can suppress the crystal grain diameter to 50 nm or less in such a part, and it becomes possible to attain the improvement of TDDB characteristics at the same time.

Further, with such stacked gate electrode structures 24GA and 24GB, it becomes possible to secure sufficiently large film thickness for the gate electrode structure as a whole, and it becomes possible to carry out the silicide formation process without damaging the gate insulation film.

Thus, because the ion implantation process to the lower polysilicon film is conducted separately to the ion implantation process for the formation of source and drain regions as shown in FIGS. 9G and 9H, it becomes possible to guarantee sufficient impurity concentration level for the lower part of the stacked polysilicon gate electrode structure and thus for the polysilicon films 23A and 23B, even in the case of forming shallow junction at the source and drain regions by using reduced ion implantation energy for suppressing short channel effect. Thus, it becomes possible to set the overall height of the stacked gate electrode structure a height sufficient for silicide formation.

Because the undoped polysilicon film 34 is patterned with the patterning process of FIG. 9K with the present embodiment, the patterning proceeds simultaneously in the device region 10A and in the device region 10B, and problem such as the etching becomes excessive in one of the device regions and insufficient in the other device region is avoided.

### SECOND EMBODIMENT

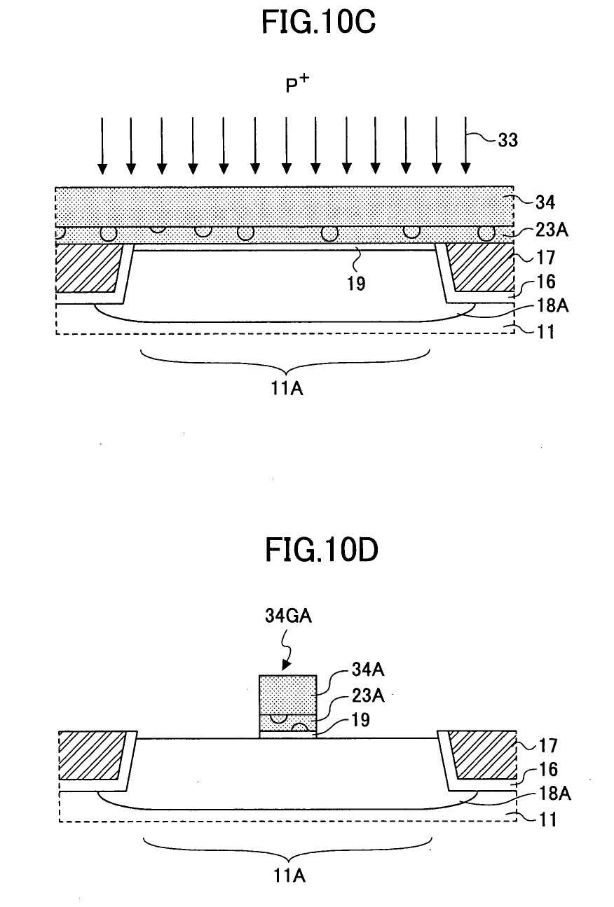

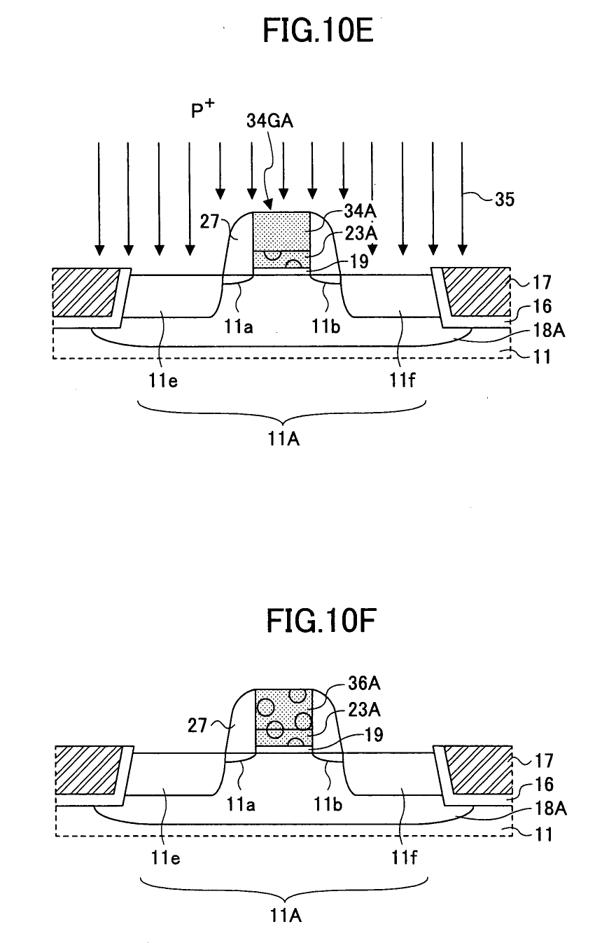

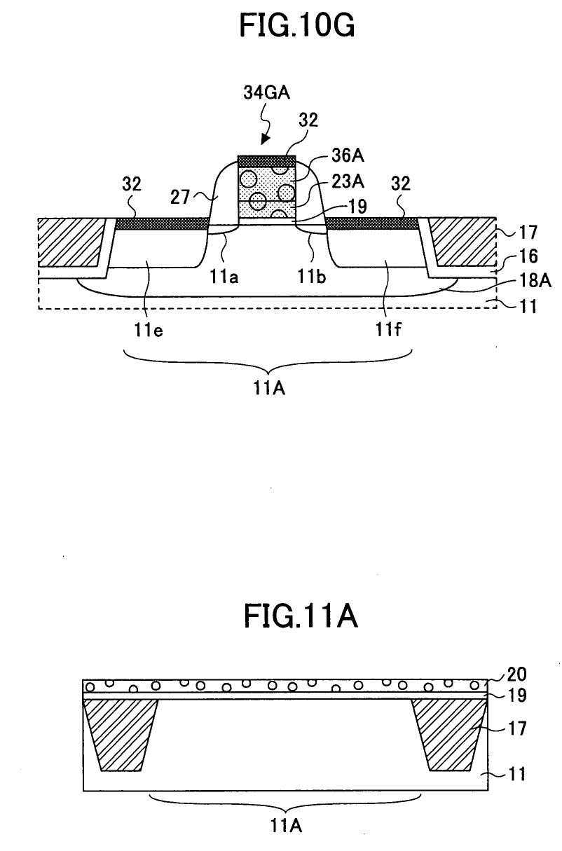

Next, the fabrication process of a semiconductor device according to a second embodiment of the present invention will be described with reference to FIGS. 10A-10G, wherein those parts corresponding to the parts explained previously are designated by the same reference numerals and the description thereof will be omitted. In the present embodiment, too, a CMOS device is fabricated, while in the description hereinafter, only the process for the n-channel MOS transistor in the CMOS device will be explained.

Referring to FIG. 10A, there is formed a polysilicon film 23A doped to n-type on the gate insulation film 19 in correspondence to the device region 11A similarly to the process of FIGS. 9A-9I, and the polysilicon film 24 is formed in the step of FIG. 10B on the polysilicon film 23A similarly to the step of FIG. 9J by a low-pressure CVD process at the substrate temperature of 580-620° C., such as 600° C. for example, with a film thickness of 50-100 nm. Similarly to the step of FIG. 9J, the film thickness of the polysilicon film 24 is set to be larger than the film thickness of the polysilicon film 23A with the present embodiment and such that the total thickness of the polysilicon films 23A and 23 becomes 100 nm. Further, it should be noted that the grain diameter of the Si crystal grains in the polysilicon film 24 is larger than the Si crystal grains in the polysilicon film 23. While not illustrated, the polysilicon film 24 is formed on the polysilicon film 23B in the device region 11B for the p-channel MOS transistor.

Next, in the step of FIG. 10C, the present embodiment conducts an ion implantation process of P ions 33 into the polysilicon film 24 under the acceleration voltage of 10-30 keV, such as 20 keV for example, with the dose of 4-8×10¹⁵ cm⁻², such as 5×10¹⁵ cm⁻² while using a resist pattern (not shown) exposing the device region 11A, and dope the pertinent part of the polysilicon film 24 to n-type. Similarly, the present embodiment conducts an ion implantation process of B ions into the polysilicon film 24 under the acceleration voltage of 5-10 keV, such as 8 keV for example, with the dose of 3-6×10¹⁵ cm⁻², such as 4×10¹⁵ cm⁻² while using a resist pattern (not shown) exposing the device region 11B, and dope the pertinent part of the polysilicon film 24 to p-type. With this state, it should be noted that the polysilicon film 24 is transformed to an amorphous film 34 of amorphous state as a result of the ion implantation process as shown in FIG. 10C.

Next, in the step of FIG. 10D, the polysilicon film 23A and the amorphous silicon film 24 of FIG. 10C are patterned and there is formed a stacked gate electrode pattern 34GA with a gate length of 60 nm, for example. Further, by a similar process, a stacked gate electrode pattern doped to p-type is formed in the device region 11B. Further, as a result of such a patterning process, the gate insulation film 19 undergoes patterning and the gate insulation film 19 is thereby removed except for the part right underneath the stacked gate electrode structure.

Incidentally, in the event the patterning of the stacked gate electrode pattern is conducted in the device region 11B not illustrated simultaneously to the patterning process of FIG. 10D, it is necessary to optimize the etching condition in view of the fact that the n-type region and p-type region are etched at the same time in the amorphous silicon film 34, for avoiding occurrence of excessive etching in one of the p-type and n-type regions and under etching in the other of the p-type and n-type regions.

Next, in the step of FIG. 10E, there is formed a resist pattern (not shown) exposing the device region 11A on the structure of FIG. 10D, and ion implantation process of P ions is conducted under the condition similar to the one used before while using the resist pattern and the stacked gate electrode pattern 34GA as a mask. With this, source and drain extension regions of n-type are formed in the device region 11A at respective lateral sides of the stacked gate electrode pattern 34G. Further, source and drain extension regions of p-type are formed also in the device region 11B by conducting ion implantation process of B ions under the condition similar to the one described before.

Next, in the step of FIG. 10E, the sidewall insulation films 27 are formed on the stacked gate electrode pattern 34G in the device region 11A and also on the similar stacked gate electrode pattern formed in the device region 11B, and the source and drain regions 11e and 11f of n⁺-type are formed in the device region 11A at the outer sides of the sidewall insulation films 27 by conducting ion implantation process of P ions 35 under the condition similar to the one explained before, while using the resist pattern exposing the device region 11A, the stacked gate electrode pattern 34GA and the sidewall insulation films 27 as a mask. Further, by conducting ion implantation of B ions in the device region 11B similarly, source and drain regions and of p⁺-type are formed in correspondence to the source and drain regions 11g and 11h of p⁺-type.

Further, by applying a thermal annealing process to the structure of FIG. 10E in the step of FIG. 10F in a nitrogen gas ambient at the temperature of 1000-1050° C. for 0-10 seconds, the impurity elements thus introduced are activated. Further, as a result of the thermal annealing process of FIG. 10F, there is caused crystallization in the amorphous silicon layer 34A, and the amorphous silicon layer 34A is transformed to a polysilicon layer 36A. Similar crystallization takes place also in the device region 11B.

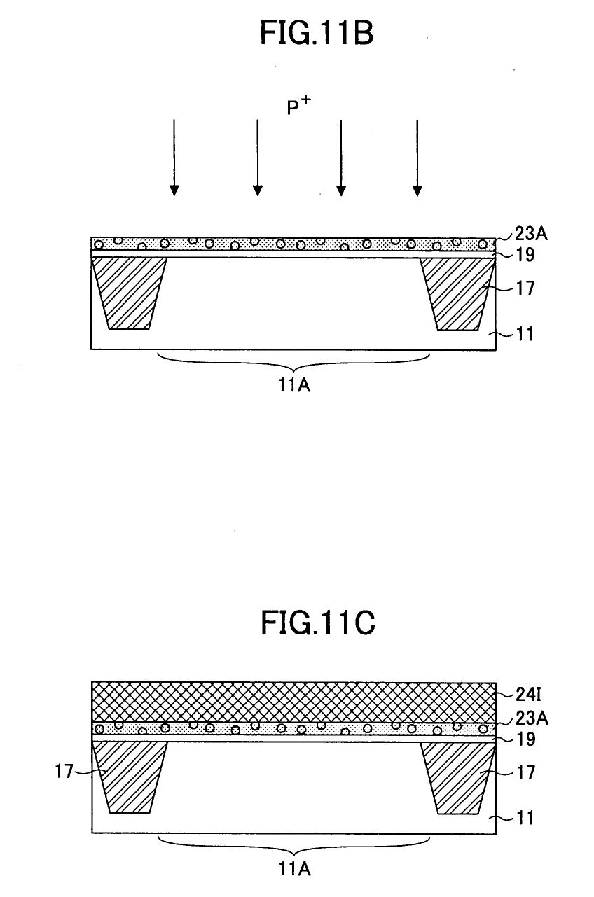

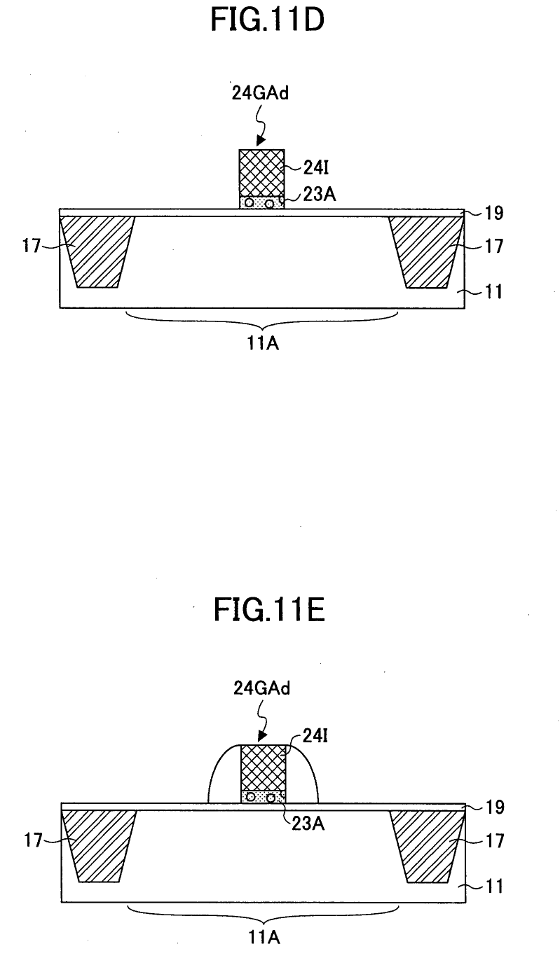

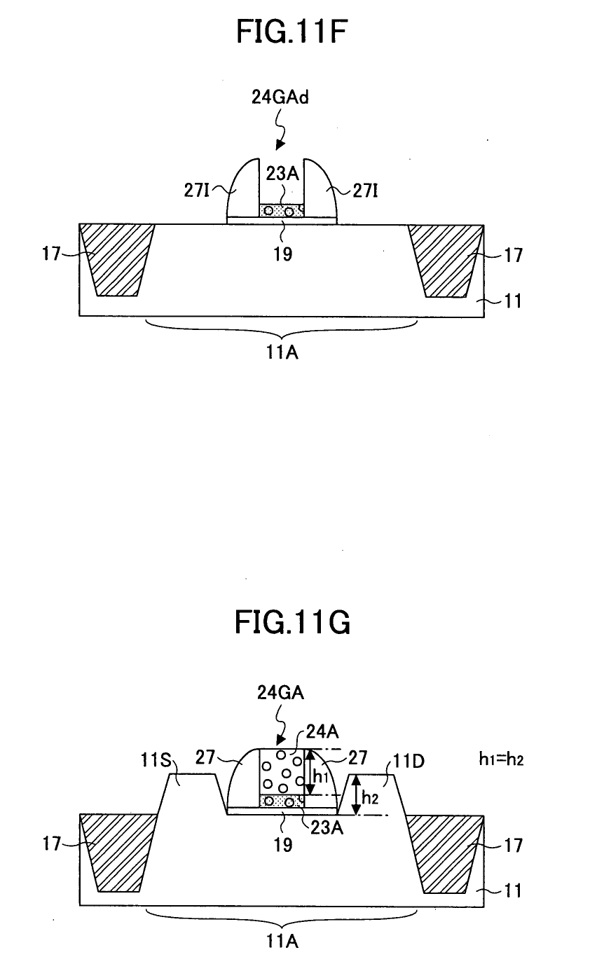

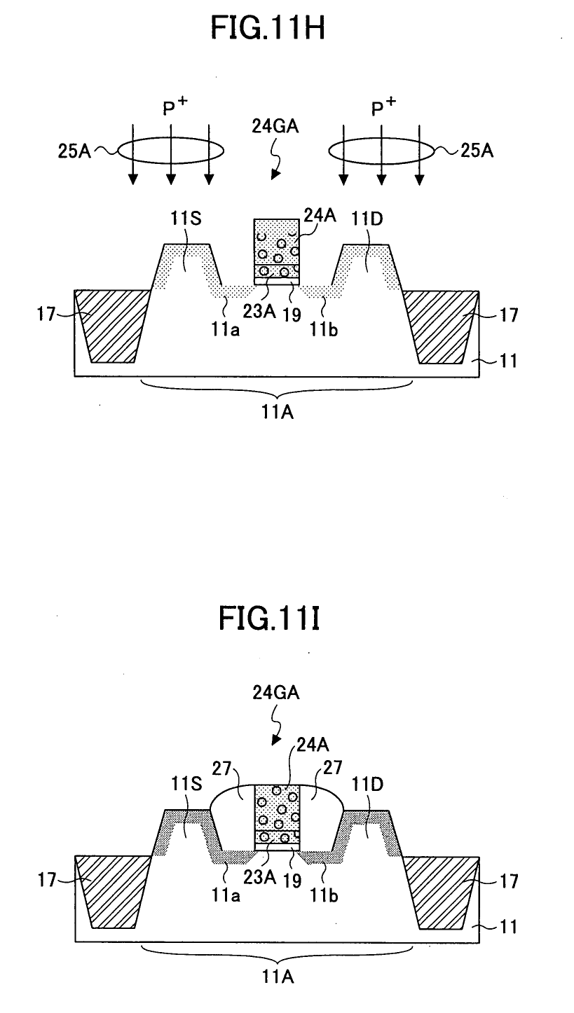

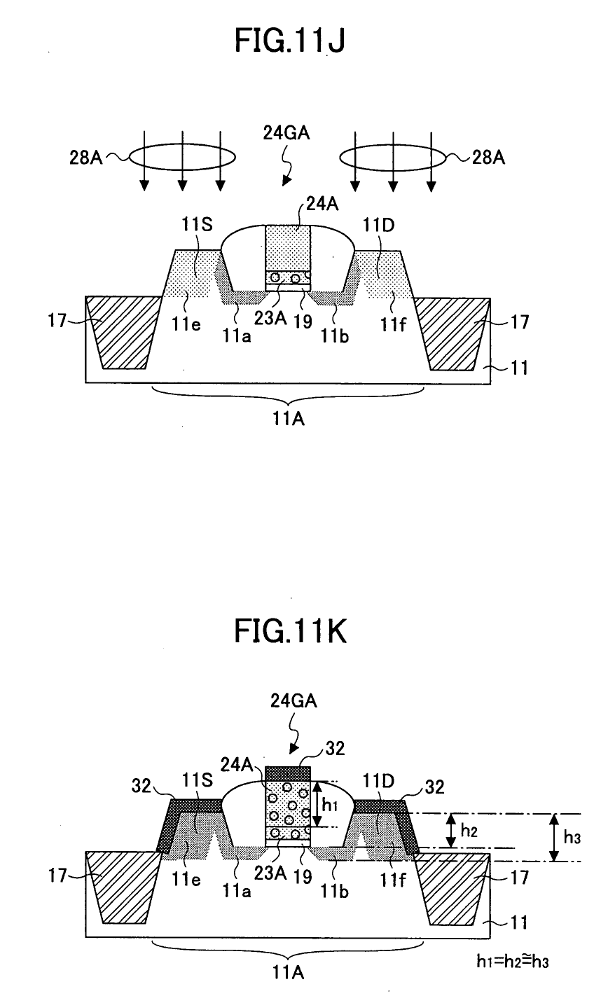

Further, a Co film is deposited on the structure of FIG. 10F by a sputtering process, and after thermal annealing process, unreacted Co film is removed by etching. Further, by applying a thermal annealing process again, there is obtained a structure in which the CoSi₂ films 32 are formed on the source and drain regions 11e and 11f and further on the polysilicon film 36A in the device region 11A as shown in FIG. 11G. Further, similar structure having the CoSi₂ films is formed also in the device region 11B.

Further, by forming an interlayer insulation film not illustrated on the structure of FIG. 10F and forming via contact structure and interconnection structure according to the needs, there is completed a CMOS device in which the n-channel MOS transistor and the p-channel MOS transistor are connected in series. Further, in the case of forming an upper level interconnection structure on the interlayer insulation film in the form of a multilayer interconnection structure by using a damascene process, there are conducted formation of interconnection trenches and via-holes after formation of the interlayer insulation film, and a Cu interconnection layer is formed so as to fill such interconnection trenches and the via-holes. Further, excessive Cu layer on the interlayer insulation film is removed by a CMP process. If more complex interconnection structure is desired, such a process may be repeated as necessary.

According to the semiconductor device of the present embodiment thus formed, too, it should be noted that the lower polysilicon film is introduced with the impurity element of the corresponding conductivity type in each of the stacked gate electrode structures 24GA and 24GB before the upper polysilicon film is formed with low acceleration energy and high impurity concentration level, and it becomes possible to effectively resolve the problem of depletion caused in the polysilicon gate. Further, in view of small film thickness of the lower polysilicon film, the present invention can suppress the crystal grain diameter to 50 nm or less in such a part, and it becomes possible to attain the improvement of TDDB characteristics at the same time.

Further, with such stacked gate electrode structure, it becomes possible to secure sufficiently large film thickness for the gate electrode structure as a whole, and it becomes possible to carry out the silicide formation process without damaging the gate insulation film.

Thus, because the ion implantation process to the upper polysilicon film is conducted separately to the ion implantation process for the formation of source and drain regions with the present embodiment, it becomes possible to guarantee sufficient impurity concentration level for the stacked polysilicon gate electrode structure when forming shallow junction at the source and drain regions by using reduced ion implantation energy for suppressing short channel effect, even when the thickness of the polysilicon film forming the upper part of the stacked polysilicon gate electrode structure is increased. Thus, it becomes possible to set the overall height of the stacked gate electrode structure a height sufficient for silicide formation.

In each of the embodiments described heretofore, it is also possible to use other n-type impurity elements such as As (arsenic) in place of P.

Because the problem of deterioration of TDDB characteristics appears conspicuously in n-channel MOS transistors, it is also possible to carry out the separated ion implantation processes to the lower polysilicon film 20 and to the upper polysilicon film 24A explained with reference to FIGS. 9G and 9L only for n-channel MOS transistors, while carrying out simultaneous ion implantation process into the upper layer 24B and the lower layer 23B of the stacked gate electrode structure for p-channel MOS transistors.

### THIRD EMBODIMENT

Next, fabrication process of a semiconductor device according to a third embodiment of the present invention that suppresses short channel effect with reference to FIGS. 11A-11K, wherein those parts corresponding to the parts explained previously are designated by the same reference numerals and the description thereof will be omitted.

In the explanation hereinafter, only n-channel MOS transistor will be explained similarly as before, while it should be noted that the explanation is applicable also to p-channel MOS transistors. Further, it is possible to construct a dual gate device such as a CMOS device, by combining the n-channel MOS transistor of the present embodiment with a p-channel MOS transistor formed by a similar process.

Referring to FIG. 11A, the silicon substrate 11 is formed with the device region 11A and the device region 11B not illustrated by the device isolation region 17 of STI structure, and the undoped polysilicon film 20 is formed on the gate insulation film 19 by a low-pressure CVD process by conducting the process of FIGS. 9A-9E explained before under the condition similar to the previous embodiments with the film thickness of 10-50 nm. In the explanation hereinafter, illustration of the thermal oxide film 16 formed between the device isolation insulation film 17 and the silicon substrate 11 will be omitted.

Further, in the step of FIG. 11B, the resist pattern exposing the device region 11A is formed on the polysilicon film 20 of FIG. 11A, and P is introduced by an ion implantation process conducted under the acceleration energy of 3-30 keV with the dose of 1-3×10¹⁵ cm⁻² while using the resist pattern as a mask. Thereby, the polysilicon film 20 is converted once to an amorphous state, and the n-type polysilicon film 23A is obtained as a result of applying an activation thermal annealing process thereto. Further, a p-type polysilicon film is formed by introducing B into the polysilicon film 20 in the device region 10B by an ion implantation process.

The n-type polysilicon film 23A and the corresponding p-type polysilicon film thus formed have a film thickness of 10-50 nm and hence are formed by the Si crystal grains having the grain diameter of 10-50 nm.

Next, in the step of FIG. 11C, a dummy insulation film 24I having an etching selectivity against the device isolation insulation film 17 formed on the silicon substrate 11 is formed over the device regions 11A and 11B for example by an SiN film by conducting a low-pressure CVD process with a thickness of 50-100 nm, such that the dummy insulation film 24I covers the n-type polysilicon film 23A and the corresponding p-type polysilicon film on the device region 11B.

Next, in the step of FIG. 11D, the dummy insulation film 24I and the polysilicon film 23A underneath are patterned in the device region 11A and a dummy gate structure 24GAd is formed in correspondence to the desired gate electrode. Further, similar dummy gate structure is formed also in the device region 11B.

Next, in the step of FIG. 11E, there are formed dummy sidewall insulation films 27I on the dummy gate structure 24GAd by a high-density plasma CVD process and subsequent etchback process, wherein the dummy sidewall insulation films 27I are formed of a material such as SiO₂ having etching selectivity against the dummy insulation film 24I. Similar dummy sidewall insulation films are formed also in the device region 11B on the dummy gate structure corresponding to the dummy gate structure 24GAd.

Next, in the step of FIG. 11F, the dummy insulation film 24I is selectively etched from the foregoing dummy gate electrode structure 24GAd and also from the corresponding dummy gate structure formed in the device region 11B, and with this, the polysilicon gate film 23A is exposed. At the same time, the surface of the silicon substrate 11 is exposed at the outer sides of the dummy sidewall insulation films 27I. In the case the film thickness of the gate insulation film 19 is small, there may be the cases in which the surface of the silicon substrate 11 is already exposed in the patterning step of FIG. 11D.

Similarly, the p-type polysilicon film corresponding to the n-type polysilicon film 23A and the surface of the silicon substrate 11 are exposed also in the device region 11B. The selective etching process of the dummy insulation film 24I can be conducted by a wet etching process that uses pyrophosphoric acid etchant.

Next, in the step of FIG. 11G, epitaxial growth of a silicon layer is conducted on the structure of FIG. 11F by a low-pressure CVD process after removing native oxide film by DHF, wherein the epitaxial growth of the silicon layer may be conducted at the temperature of 700-800° C., typically 750° C., while using dichlorosilane, hydrogen chloride and hydrogen, and there are formed epitaxial regions 11S and 11D at respective outer sides of the dummy sidewall insulation films 27I with a height of 50-100 nm as measured from the interface between the silicon substrate 11 and the gate insulation film 19.

Further, with such epitaxial growth of the silicon layer in the step of FIG. 11G, there occurs growth of the polysilicon film 24A on the n-type polysilicon film 23A up to the top edge of the dummy sidewall insulation films 27I, and with this, a structure identical to the stacked gate electrode structure 24GA explained previously is formed. Thereby, it should be noted that the height h1 of the polysilicon film 24A coincides with the height h2 of the epitaxial regions 11S and 22D (h1=h2) measured from the interface between the silicon substrate 11 and the gate insulation film 19.

Further, in the step of FIG. 11H, the dummy sidewall insulation films 27I are removed, and the P ions 25A are introduced into the substrate 11 by an ion implantation process similarly to the process of FIG. 9L so as to include the epitaxial regions 11S and 11D while using the stacked gate electrode structure 24GA as a self-alignment mask. With this, there are formed a source extension region 11a and a drain extension region 11b of n-type at respective lateral sides of the stacked gate electrode structure 24GA. Further, similar source and drain extension regions of p-type are formed in the device region 11B. It should be noted that FIG. 11H shows the state in which the top part of the polysilicon film 24A has caused transition to amorphous state as a result of the ion implantation process.

Next, in the step of FIG. 11I, sidewall insulation films 27 of SiO₂ are formed at respective lateral sides of the stacked gate electrode structure 24G of FIG. 11H by a high-density plasma CVD process so as to expose the epitaxial regions 11S and 11D, and P ions 28A are introduced into the device region 11A in the step of FIG. 11J under the condition similar to the step of FIG. 9O explained previously. With this, the source and drain regions 11e and 11f doped to n⁺-type are formed in the epitaxial regions 11S and 11D and the entirety of the polysilicon film 24A is doped to n⁺-type. As a result of such an ion implantation process, the entirety of the polysilicon film 24A changes to amorphous state.

Further, similar ion implantation process of p-type impurity element such as B is conducted into the device region 11B.

Next, in the step of FIG. 11K, the structure of FIG. 11J is annealed at the temperature of 1000-1050° C. for 0-10 seconds for activation of the impurity elements introduced in the previous ion implantation processes, and after formation of the silicide layers 32, an n-channel MOS transistor is formed such that the n-channel MOS transistor includes source and drain regions 11e and 11f on the silicon substrate 11 such that the source and drain regions 11e and 11f projects in the upward direction beyond the interface between the silicon substrate 11 and the gate insulation film 19. As a result of such a thermal annealing process, the entirety of the polysilicon film 24A undergoes crystallization again.

Similar crystallization and silicide formation are caused also in the device region 11B not illustrated, and as a result, there is formed a p-channel MOS transistor having epitaxial regions projecting upward from the silicon substrate surface similarly to the one shown in FIG. 11K. Formation of the silicide layer 32 may be conducted by the process similar to the one explained in the previous embodiment.

As shown in FIG. 11K, the n-channel MOS transistor, and also p-channel MOS transistor, of the present embodiment has the feature that the thickness h₁ of the polysilicon film 24A and the height h₂ of the epitaxial regions 11S and 11G coincide with each other and that the height h₂ is generally coincident to the thickness h₃ of the diffusion regions 11e or 11f when the thickness of the source extension region 11a or the thickness of the drain extension region 11b is ignored (h₁=h₂≈h₃).

Thus, by setting the acceleration energy at the time of doping the source and drain regions 11e and 11f in the step of FIG. 11J by the ion implantation process of the P ions 28A, such that the P ions reach the bottom part of the polysilicon film 24A, it becomes possible to set the bottom edge of the source region 11e or drain region 11f of n⁺-type thus formed to be generally coincident to the bottom edge of the source or drain extension region 11a or 11b. As a result, the bottom edge of the source and drain regions 11e and 11f are located near the surface of the silicon substrate and it becomes possible to suppress the short channel effect effectively at the time of operation of the n-channel MOS transistor. Further, similar effect of suppressing short channel effect is attained also in the p-channel MOS transistor formed in the device region 11B.

Because the polysilicon film 24A of coarse grain structure is formed on the polysilicon film 23A of fine grain structure in the gate electrode structure with the present embodiment at the time of forming the epitaxial layers 11S and 11D, it becomes possible to attain improvement of the TDDB characteristics and suppression of depletion of the polysilicon gate electrode explained with previous embodiments simultaneously.

While it is possible with the present embodiment to form the source and drain extension regions 11a and 11b immediately after the formation of the dummy gate structure 24GAd of FIG. 11D, it becomes possible to minimize the thermal budged by conducting the formation of the source and drain extension regions 11a and 11b after the epitaxial regrowth process of FIG. 11G.

Further, while the foregoing embodiments are described for the case of conducting the activation annealing process of the impurity elements introduced by the ion implantation by dedicated thermal annealing process, it is also possible to carry out such activation processing by using other processes that includes thermal annealing process. For example, it is possible to crystallize the lower polysilicon layer by utilizing the process of depositing the upper polysilicon layer.

Further, while the present embodiment has been explained for the case of the gate insulation film formed of an SiON film, the present invention is not limited to such a specific film and it is also possible to use an siO₂ film or SiN film. Further, it is also possible to use a so-called high-K film such as a Ta₂O₅ film.

Further, the substrate 11 is not limited to a bulk silicon substrate but it is also possible to use an SOS substrate in which a silicon epitaxial layer is formed on a sapphire substrate or an SOI substrate in which a monocrystalline silicon layer in formed on a silicon substrate via an insulation film.

Further, in each of the foregoing embodiments, the substrate 11 is not limited to a silicon substrate but it is also possible to sue a SiGe mixed crystal substrate, an SiC mixed crystal substrate in which a small amount of C is added to Si, or even a SiGeC mixed crystal substrate.

In each of the foregoing embodiments, it is not necessary to form the layers constituting the gate electrode in the form of a polysilicon layer but it is also possible to form the same as an amorphous silicon layer.

Further, in each of the CMOS devices of the foregoing embodiments, the silicon layers constituting the gate electrode of the MOS transistor are not limited to polysilicon layers but it is also possible to form the gate electrode of some of the MOS transistors by a monocrystalline silicon layer.

Further, while it has been explained with the foregoing description that the gate electrode is formed of stack of polysilicon films, at least one of the lower and upper polysilicon films constituting the stacked gate electrode structure may contain Ge or C in addition to Si or both of Ge and C in addition to Si.

Further, in each of the foregoing embodiments, it is noted that the gate insulation film 19 is patterned simultaneously to the patterning process of the stacked gate electrode structures 26GA and 26GB in the step of FIG. 9K, while this is not a necessary process and it is also possible to leave the gate insulation film 19 on the surface of the silicon substrate 11 particularly in the case the gate insulation film 19 has a film thickness of 2 nm or more.

For example, it is possible to leave the gate insulation film 19 continuously on the surface of the silicon substrate in the case the gate insulation film 19 has a film thickness of 2 nm or more. In this case, the ion implantation process for forming the source extension region and the drain extension region is conducted through such remaining insulation film. On the other hand, in the case the gate insulation film 19 has a thickness of 2 nm or more and the gate insulation film 19 is not patterned spontaneously at the time of patterning the stacked gate electrode structure, it is also possible to intentionally pattern the gate insulation film 19.

While the present invention has been explained with regard to preferred embodiments, the present invention is by on means limited to such specific embodiments and various variations and modifications may be made without departing from the scope of the invention as set forth in patent claims.

According to the present invention, it becomes possible to realize a semiconductor device capable of suppressing depletion of polysilicon gate electrode and simultaneously capable of suppressing deterioration of TDDB characteristics without complicating the fabrication process. According to such a semiconductor device, doping of the polysilicon gate electrode is achieved by ion implantation process, and thus, it is possible with the present invention to form a CMOS device, or the like, having polysilicon gates of different conductivity type, with simple process.

Further, according to the semiconductor device of the present invention, it is possible to form the source/drain regions on the semiconductor substrate such that the bottom edge of the source/drain regions is located near the surface of the silicon substrate by a regrowth process concurrently to the formation of the upper polysilicon layer of the polysilicon gate structure of multilayer construction and by doping the re-grown source/drain regions thus formed to the desired conductivity type by an ion implantation process. Thereby, it becomes possible to suppress the short channel effect effectively.

What is claimed is:

1. A semiconductor device, comprising:
a substrate;
a device isolation structure formed on said substrate, said device isolation structure defining a first device region of a first conductivity type and a second device region of a second conductivity type on said substrate;
a first polycrystalline semiconductor gate electrode structure formed in said first device region via a gate insulation film, said first polycrystalline semiconductor gate electrode structure having a stacked structure in which a lower polycrystalline semiconductor layer and an upper polycrystalline semiconductor layer are stacked consecutively, said first polycrystalline gate electrode structure being doped to said second conductivity type;
a second polycrystalline semiconductor gate electrode structure formed in said second device region via a gate insulation film, said second polycrystalline semiconductor gate electrode structure having a stacked structure in which a lower polycrystalline semiconductor layer and an upper polycrystalline semiconductor layer are stacked consecutively, said second polycrystalline gate electrode structure being doped to said first conductivity type;
a pair of diffusion regions of said second conductivity type formed in said first device region at respective lateral sides of said first polycrystalline semiconductor gate electrode structure; and
a pair of diffusion regions of said first conductivity type formed in said second device region at respective lateral sides of said second polycrystalline semiconductor gate electrode structure,
wherein, in each of said first and second polycrystalline semiconductor gate electrode structures, said lower polycrystalline semiconductor layer comprises semiconductor crystal grains of a grain diameter smaller than semiconductor crystal grains constituting said upper polycrystalline semiconductor layer,
in each of said first and second polycrystalline semiconductor gate electrode structures, said lower polycrystalline semiconductor layer has a dopant concentration level equal to or higher than a dopant concentration level of said upper polycrystalline semiconductor layer.

2. The semiconductor device as claimed in claim 1, wherein, in each of said first and second polycrystalline semiconductor gate electrode structures, said lower polycrystalline semiconductor layer has a dopant concentration of 1×10²⁰ cm⁻³ or more.

3. The semiconductor device as claimed in claim 1, wherein, in each of said first and second polycrystalline semiconductor gate electrode structures, 90% of said crystal grains in said lower polycrystalline semiconductor layer have a grain diameter of 10-50 nm.

4. The semiconductor device as claimed in claim 1, wherein, in each of said first and second polycrystalline semiconductor gate electrode structures, said lower polycrystalline semiconductor layer has a film thickness of 10-50 nm.

5. The semiconductor device as claimed in claim 1, wherein, in one of said first and second polycrystalline semiconductor gate electrode structures, said lower polycrystalline semiconductor layer and said upper polycrystalline semiconductor layer are doped with P.

6. A semiconductor device, comprising:
a substrate;
a device isolation structure formed on said substrate, said device isolation structure defining a first device region of a first conductivity type and a second device region of a second conductivity type on said substrate;
a first polycrystalline semiconductor gate electrode structure formed in said first device region via a gate insulation film, said first polycrystalline semiconductor gate electrode structure having a stacked structure in which a lower polycrystalline semiconductor layer and an upper polycrystalline semiconductor layer are stacked consecutively, said first polycrystalline semiconductor gate electrode structure being doped to said second conductivity type;
a second polycrystalline semiconductor gate electrode structure formed in said second device region via a gate insulation film, said second polycrystalline semiconductor gate electrode structure having a stacked structure in which a lower polycrystalline semiconductor layer and an upper polycrystalline semiconductor layer are stacked consecutively, said second polycrystalline semiconductor gate electrode structure being doped to said first conductivity type;
a pair of diffusion regions of said second conductivity type formed in said first device region at respective lateral sides of said first polycrystalline semiconductor gate electrode structure;
a pair of diffusion regions of said first conductivity type formed in said second device region at respective lateral sides of said second polycrystalline semiconductor gate electrode structure;
wherein, in each of said first and second polycrystalline semiconductor gate electrode structures, said lower polycrystalline semiconductor layer comprises semiconductor crystal grains of a grain size smaller than semiconductor crystal grains constituting said upper polycrystalline semiconductor layer,
in each of said first and second polycrystalline semiconductor gate electrode structures, said lower polycrystalline semiconductor layer has a dopant concentration of 1×10²⁰ cm⁻³ or more.

7. The semiconductor device as claimed in claim 6, wherein, in each of said first and second polycrystalline semiconductor gate electrode structures, said lower polycrystalline semiconductor layer has a film thickness of 10-50 nm.

8. The semiconductor device as claimed in claim 6, wherein, in one of said first and second polycrystalline semiconductor gate electrode structures, said lower polycrystalline semiconductor layer and said upper polycrystalline semiconductor layer are doped with P.

9. A semiconductor device, comprising:
a substrate;
a device isolation structure formed on said substrate, said device isolation structure defining a first device region of a first conductivity type and a second device region of a second conductivity type on said substrate;
a first polycrystalline semiconductor gate electrode structure formed in said first device region via a gate insulation film, said first polycrystalline semiconductor gate electrode structure having a stacked structure in which a lower polycrystalline semiconductor layer and an upper polycrystalline semiconductor layer are stacked consecutively, said first polycrystalline gate electrode structure being doped to said second conductivity type;
a second polycrystalline semiconductor gate electrode structure formed in said second device region via a gate insulation film, said second polycrystalline semiconductor gate electrode structure having a stacked structure in which a lower polycrystalline semiconductor layer and an upper polycrystalline semiconductor layer are stacked consecutively, said second polycrystalline gate electrode structure being doped to said first conductivity type;
a pair of diffusion regions of said second conductivity type formed in said first device region at respective lateral sides of said first polycrystalline semiconductor gate electrode structure; and
a pair of diffusion regions of said first conductivity type formed in said second device region at respective lateral sides of said second polycrystalline semiconductor gate electrode structure,
wherein, in each of said first and second polycrystalline semiconductor gate electrode structures, said lower polycrystalline semiconductor layer comprises semiconductor crystal grains of a grain diameter smaller than semiconductor crystal grains constituting said upper polycrystalline semiconductor layer,
wherein, in each of said first and second polycrystalline semiconductor gate electrode structures, said lower polycrystalline semiconductor layer has a smaller film thickness as compared with said upper polycrystalline semiconductor layer.

10. The semiconductor device as claimed in claim 9, wherein, in each of said first and second polycrystalline semiconductor gate electrode structures, said lower polycrystalline semiconductor layer has a dopant concentration of 1×10²⁰ cm⁻³ or more.

11. The semiconductor device as claimed in claim 9, wherein, in each of said first and second polycrystalline semiconductor gate electrode structures, said lower polycrystalline semiconductor layer has a film thickness of 10-50 nm.

12. The semiconductor device as claimed in claim 9, wherein, in one of said first and second polycrystalline semiconductor gate electrode structures, said lower polycrystalline semiconductor layer and said upper polycrystalline semiconductor layer are doped with P.

13. The semiconductor device as claimed in claim 1, wherein at least a part of said pair of diffusion regions is formed in at least said first device, region at an elevated location higher than a level of an interface between said substrate and said gate insulation film.

14. The semiconductor device as claimed in claim 13, wherein said elevated location is elevated with a height generally corresponding to a film thickness of said upper polycrystalline semiconductor layer as measured from said interface.

15. The semiconductor device as claimed in claim 13, wherein a lower edge of said pair of diffusion regions is formed in said elevated location at a depth level generally corresponding to a film thickness of said upper polycrystalline semiconductor layer.

16. The semiconductor device as claimed in claim 6, wherein at least a part of said pair of diffusion regions is formed at an elevated location higher than a level of an interface between said substrate and said gate insulation film.

17. The semiconductor device as claimed in claim 16, wherein said elevated location is elevated with a height generally corresponding to a film thickness of said upper polycrystalline semiconductor layer as measured from said interface.

18. The semiconductor device as claimed in claim 16, wherein a lower edge of said pair of diffusion regions is formed in said elevated location at a depth level generally corresponding to a film thickness of said upper polycrystalline semiconductor layer.

19. The semiconductor device as claimed in claim 9, wherein at least a part of said pair of diffusion regions is formed at an elevated location higher than a level of an interface between said substrate and said gate insulation film.

20. The semiconductor device as claimed in claim 19, wherein said elevated location is elevated with a height generally corresponding to a film thickness of said upper polycrystalline semiconductor layer as measured from said interface.
